(19) United States
(12) Patent Application Publication
(10) Pub. No.: US 2016/0061884 A1
(43) Pub. Date: Mar. 3, 2016

(54) CONTACT STRUCTURE FOR A TEST HANDLER, TEST HANDLER HAVING THE CONTACT STRUCTURE AND METHOD OF TESTING INTEGRATED CIRCUIT DEVICES USING THE TEST HANDLER

(71) Applicant: Samsung Electronics Co., Ltd., Suwon-si (KR)

(72) Inventors: Jung-Hyun CHO, Daejeon (KR); Byoung-Jun MIN, Asan-si (KR); Joong-Kyeon PARK, Busan (KR)

(21) Appl. No.: 14/788,776

(22) Filed: Jun. 30, 2015

(30) Foreign Application Priority Data
Aug. 28, 2014 (KR) 10-2014-0113289

(51) Int. Cl. G01R 31/28; G01R 31/26

(52) U.S. Cl. CPC G01R 31/2867; G01R 31/2877; G01R 31/2875; G01R 31/26

(57) ABSTRACT

A contact structure for a test handler for electrically testing a semiconductor device, comprising: a base body configured to be driven by a driving unit; at least one first pusher assembly arranged on the base body and configured to push and cool the semiconductor device; and at least one second pusher assembly arranged on the base body and configured to push and heating the semiconductor device.

### CROSS-REFERENCE TO RELATED APPLICATIONS

This application claims under 35 U.S.C §119 to Korean Patent Application No. 10-2014-0113289 filed on Aug. 28, 2014 in the Korean Intellectual Property Office, the disclosure of which is incorporated by reference herein in its entirety.

### BACKGROUND

1. Field

Embodiments relate to a contact structure, a test handler, and a method of testing semiconductor devices, and more particularly, to a contact structure and a test handler having the contact structure for testing semiconductor devices and a method of testing semiconductor devices using the test handler.

2. Description of the Related Art

Fabricated semiconductor devices usually undergo an electrical die sorting (EDS) process in which malfunctioning chips or dies on a wafer are sorted into bad chips or dies. The EDS process may be performed by an automatic test equipment (ATE) in which the device under test (DUT) is automatically connected to a test center by a test handler and an electrical test and measurement may be performed using the DUT by the test center.

The DUT is loaded into the test chamber and may be connected to a test socket by the test handler. The testing apparatus transfers testing signals to the DUT through the test socket for electrical test to the DUT. Testing results on the DUT are evaluated by the testing apparatus or other evaluating unit of the ATE. The DUT is sorted into a bad chip or a good chip according to the evaluation results and is transferred and stacked in a bad chip stack or a good chip stack by the test handler.

Multiple DUTs are generally inserted into an inserter of a test tray in the conventional test chamber and the test tray is guided into the test socket by using a contact structure. Recently, a hot test for testing the DUT under a high temperature and a cold test for testing the DUT under a low temperature may be performed in the same test chamber for increasing the accuracy of the test results.

In such a case, the DUT is heated or cooled through thermal conduction in the single test chamber by a temperature controller that is provided with a contact pusher of the contact structure.

However, since the DUT is heated and cooled or vice versa by the same contact pusher, the contact pusher necessarily requires a conversion time for converting between the hot test and the cold test. Thus, the electrical test to the DUT is necessarily stopped for the conversion time, which results in an increase of an overall EDS time.

### SUMMARY

An embodiment includes a contact structure for a test handler for electrically testing a semiconductor device, comprising: a base body configured to be driven by a driving unit; at least one first pusher assembly arranged on the base body and configured to push and cool the semiconductor device; and at least one second pusher assembly arranged on the base body and configured to push and heating the semiconductor device.

An embodiment includes a test handler for electrically testing a semiconductor device, comprising: a test head having test sockets configured to apply testing signals to a devices under test (DUTs) and responsive signals are detected from the DUTs; a test chamber connected to the test head and configured to receive a test tray including a plurality of DUTs arranged in correspondence to the test socket; and a contact structure positioned in the test chamber and configured to bring the DUTs in the test tray into contact with sockets of the test socket, respectively. The contact structure includes: a base body configured to be moved by a driving unit; a plurality of first pusher assemblies arranged on the base body and configured to push and cool each of DUTs; and a plurality of second pusher assemblies arranged on the base body separate from the first pusher assemblies and configured to pushing and heat each of the DUTs.

An embodiment includes a contact structure for a test handler for electrically testing a semiconductor device, comprising: a test socket configured to receive a plurality of devices under test (DUTs); a plurality of first pusher assemblies, each first pusher assembly configured to push a first at least one of the DUTs towards the test socket; a plurality of second pusher assemblies, each second pusher assembly configured to push a second at least one of the DUTs towards the test socket; a driving unit coupled to the first and second pusher assemblies and configured to move the first and second pusher assemblies such that each DUT is contacted by a first pusher assembly during a first test and by a second pusher assembly during a second test.

### BRIEF DESCRIPTION OF THE DRAWINGS

These and other features will become more apparent by describing in detail embodiments with reference to the accompanying drawings of which:

FIG. 1 is a structural view illustrating a test handler according to an embodiment;

FIG. 2 is an exploded perspective view illustrating a contact structure, a test tray and a test socket of the test handler shown in FIG. 1;

FIG. 3 is a cross-sectional view illustrating the DUT and the contact structure in FIG. 2 that makes contact with each other;

FIG. 4 is a perspective view illustrating the first pusher assembly of the contact structure shown in FIG. 2;

FIG. 5 is a perspective view illustrating the second pusher assembly of the contact structure shown in FIG. 2;

FIG. 6 is a perspective view illustrating a first modified example of the contact structure of the test handler shown in FIG. 1 according to an embodiment;

FIG. 7 is a perspective view illustrating a modification of the first modified example of the contact structure shown in FIG. 6 according to an embodiment;

FIG. 8 is a perspective view illustrating a second modified example of the contact structure of the test handler shown in FIG. 1 according to an embodiment;

FIG. 9 is a perspective view illustrating a third modified example of the contact structure of the test handler shown in FIG. 1 according to an embodiment;

FIG. 10A is a perspective view illustrating a first modification of the third modified contact structure shown in FIG. 9 according to an embodiment;

FIG. 10B is a perspective view illustrating a second modification of the third modified contact structure shown in FIG. 9 according to an embodiment;

FIG. 11A is a perspective view illustrating a fourth modified example of the contact structure of the test handler shown in FIG. 1 according to an embodiment;

FIG. 11B is a view illustrating an operation of the contact structure shown in FIG. 11A according to an embodiment;

FIG. 12 is a flow chart showing processing steps for a method of electrically testing DUTs by using the test handler shown in FIG. 1 according to an embodiment;

FIG. 13 is a flow chart showing the steps for alternately performing the cold test and the hot test by using the contact structure shown in FIG. 6 according to an embodiment;

FIGS. 14A and 14B are a flow chart showing the steps for alternately performing the cold test and the hot test by using the contact structure shown in FIG. 8 according to some embodiments; and

FIG. 15 is a flow chart showing the steps for alternately performing the cold test and the hot test by using the contact structure shown in FIG. 9 according to an embodiment.

### DETAILED DESCRIPTION OF THE EMBODIMENTS

Various embodiments will be described more fully hereinafter with reference to the accompanying drawings, in which particular embodiments are shown. Embodiments may, however, take many different forms and should not be construed as limited to the particular embodiments set forth herein. Rather, these embodiments are provided so that this disclosure will be thorough and complete, and will fully convey the scope to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings herein.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be explained in detail with reference to the accompanying drawings.

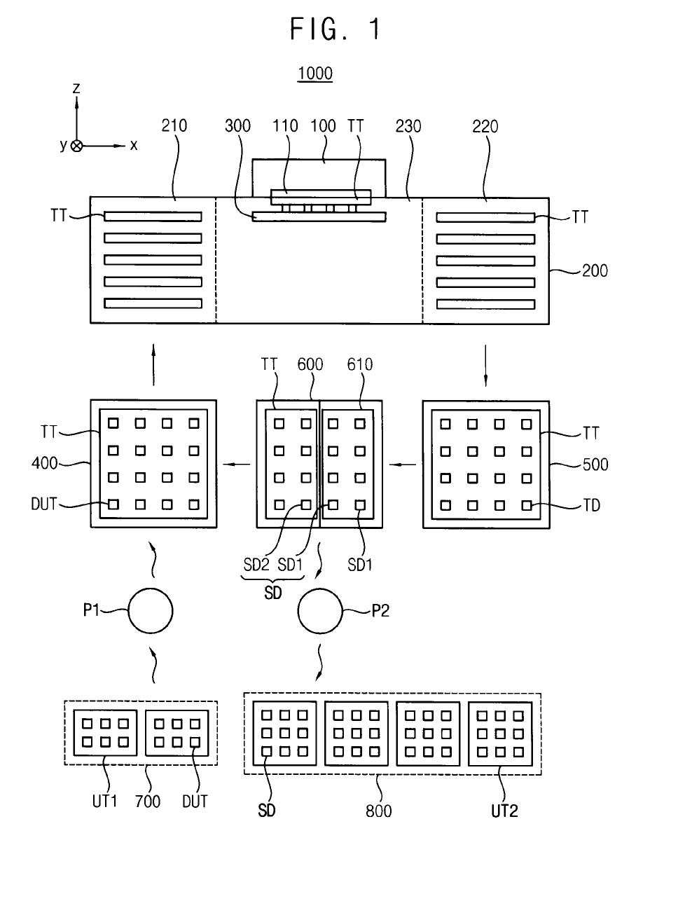

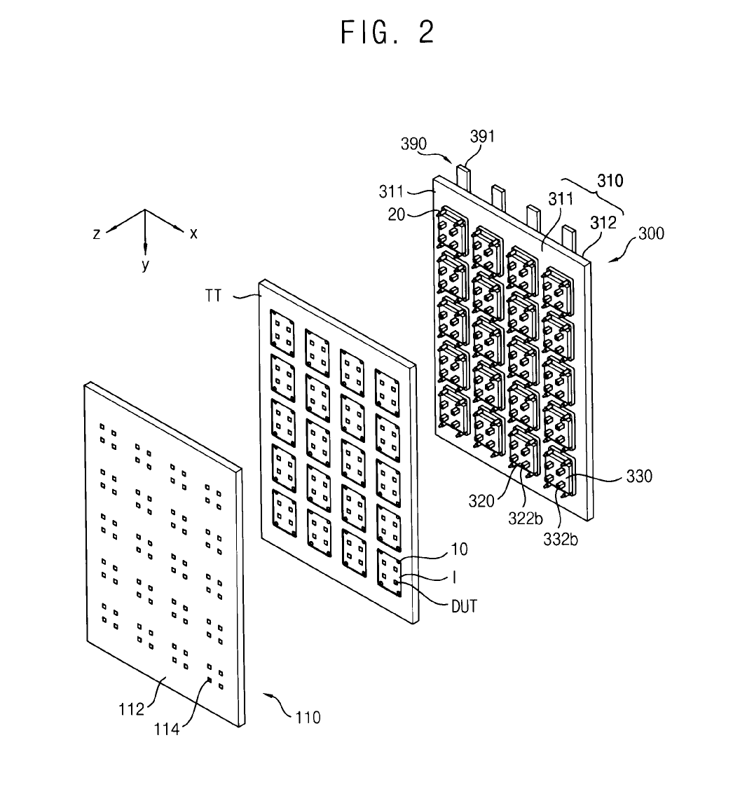

FIG. 1 is a structural view illustrating a test handler according to an embodiment. FIG. 2 is an exploded perspective view illustrating a contact structure, a test tray and a test socket of the test handler shown in FIG. 1. Referring to FIGS. 1 and 2, the test handler 1000 according to an embodiment may include a test head 100 connected to a test center for electrically testing a device under test (hereinafter, referred to as DUT) and having a test socket 110 through which testing signals may be applied to the DUT from the test center (not shown) and responsive signals may be detected and transferred to the test center from the DUT in response to the testing signals, a test chamber 200 connected to the test head 100 in such a configuration that a test tray TT receiving multiple DUTs may be arranged in correspondence to the test socket 110 and a contact structure 300 positioned in the test chamber 200 and configured to bring the DUT in the test tray TT into contact with the test socket 110.

The test handler 1000 may further include a tray loader 400 for positioning the DUT into the test tray TT and loading the test tray TT with multiple DUTs into the test chamber 200, a tray unloader 500 for unloading the test tray TT with multiple tested device (hereinafter, referred to as TD) from the test chamber 200 and a sorter 600 configured to sort the TDs into sorted devices SD having good devices SD1 and bad devices SD2.

Multiple DUTs may be received in first user tray UT1 and multiple first user trays UT1 may be received in a first stacker 700. The DUTs in the first stacker 700 may configured to be on standby for the electrical testing in the test center. The tested devices TD may be sorted into the good devices SD1 having no functional defects and the bad devices SD2 having some functional defects in sorter 600 and the sorted devices SD may be received into the second user tray UT2 from the sorter 600. Multiple second user trays UT2 may be stacked in a second stacker 800.

The DUT may be transferred to the test tray TT in the tray loader 400 from the first user tray UT1 by a first picker P1. The tested device TD may be transferred to the second user tray UT2 from the test tray TT in the sorter 600 by a second picker P2.

The test tray TT may be positioned in a horizontal state in the tray loader 400 and multiple inserts I may be prepared in the test tray TT. The DUT may be inserted into each insert I of the test tray TT, so that multiple DUTs may be received in the test tray TT.

The electrical test of the DUT may be performed on each unit of the test tray TT. When the test tray TT is loaded into the test chamber 200, multiple DUTs in the test tray TT may be simultaneously loaded into the test chamber 200 and the electrical test may be simultaneously performed on the DUTs in the test tray TT in the test chamber 200. For example, the DUTs may be arranged into a matrix shape in the test tray TT.

After completing the test of the DUTs in the test tray TT, the test tray receiving multiple tested devices TD may be unloaded from the test chamber 200 by the tray unloader 500. Thereafter, the tested devices TD may be separated from the test tray TT.

When separated from the test tray TT, the tested devices TD may be transferred to the sorter 600 and may be sorted into the good devices SD1 and bad devices SD2 in the sorter 600. The good devices SD1 and the bad devices SD2 may be individually stacked in a respective sorting table 610. For example, the good devices SD1 may be stacked in a good chip table and the bad devices SD2 may be stacked in a bad chip table. The sorted devices SD may be picked up from the sorting table 610 by the second picker P2 and then may be transferred into the second user tray UT2. Thus, multiple sorted devices SD may be received into the second user tray UT2 and multiple second user tray UT2 may be stacked in the second stacker 800.

The tray loader 400 and the tray unloader 500 may be connected to the test chamber via a transfer unit such as a transfer rail. In addition, the tray loader 400 may further include a vertical changer (not shown) for changing the position of the test tray TT from the horizontal state in the tray loader 400 to a vertical state in the test chamber 200. That is, the horizontal test tray TT in the tray loader 400 may be changed into the vertical state by the vertical changer and then may be loaded into the test chamber 200. The test tray TT may be arranged in the vertical state in the test chamber 200 and test handler 1000 test socket 110 may also be vertically positioned towards the test chamber 200. The test tray TT may face the test socket 110 in the vertical state, so that the electrical test to the DUTs may be performed in such a state that the test tray TT and the test socket 110 may face each other in the vertical state. In addition, the tray unloader 500 may also further include a horizontal changer (not shown) for changing the vertical test tray into the horizontal state. Therefore, the test tray TT may be arranged in the horizontal state from the vertical state. Although a particular horizontal or vertical orientation of elements of the test chamber 200, a changer, or the like have been described above, in other embodiments, the elements of the test chamber 200, a changer, or the like may have different orientations. Moreover, the elements of the test chamber 200, a changer, or the like may have similar orientations so that a change in orientation is not performed.

The test chamber 200 may include a first chamber 210 connected to the tray loader 400 and to which the test tray TT receiving the DUTs may be transferred, a second chamber 220 connected to the tray unloader 500 and from which the test tray TT receiving the tested devices TD may be transferred and a third chamber 230 interposed between the first and the second chambers 210 and 220 and in which the electrical test of the DUT is performed.

A pre-test treatment may be performed to the test tray TT including the DUTs in the first chamber 210 prior to the electrical test of the DUT in the third chamber 230 and a post-test treatment may be performed on the test tray TT including the tested devices TD in the second chamber 220 after to the electrical test of the DUT in the third chamber 230. For example, the first chamber 210 may include a soak chamber in which the temperature of the DUT may be preliminary increased for the electrical test in the third chamber 230 and the second chamber 220 may include a de-soak chamber in which the temperature of the tested device TD may be returned to a room temperature from the test temperature in the third chamber 230. Although returning to the room temperature has been used as an example, the de-soak chamber may be configured to change the temperature of the tested device TD to any desired temperature.

The first and the second chambers 210 and 220 may be selectively provided with the test chamber 200 according to the structures and configurations of the third chamber 230 and the test technology to the DUT in the third chamber 230. For example, when the temperature of the DUT may reach the test temperature in the third chamber 230 for a sufficiently short time, no soak chamber may be needed in the test chamber 200. In addition, when the temperature of the tested device TD may be recovered to a room temperature for a short time after completing the test in the third chamber 230, no de-soak chamber may be needed in the test chamber 200. Further, the de-soak chamber may be included not with the test chamber 200, but with the tray unloader 500. In such a case, the spaces for the first and the second test chambers 210 and 220 may be allocated to the third chamber 230 and thus the overall space of the test chamber 200 may be used for the electrical test to the DUT. Therefore, more test trays TT may be tested in the test process, thereby increasing the efficiency of the test process.

The test tray TT in the first chamber 210 may be transferred to the third chamber 230, and may be arranged to face the test socket 110 of the test head 100 in the vertical state. Multiple sockets may be arranged on the test socket 110 and the DUTs may be arranged to the sockets by one-to-one. The DUTs may be inserted into the sockets of the test socket 110, respectively, and the electrical test to the DUTs in the test tray TT may be initiated through the test head 100.

When completing the test process to the DUTs in the test tray TT, the test tray TT receiving the tested devices TD may be transferred to the second chamber 220. For example, a transfer rail (not shown) may be provided between the third and the second chambers 230 and 220, and the test tray TT receiving the tested devices TD may be transferred to the second chamber 220 along the transfer rail.

The test head 100 may be interposed between the third chamber 230 and the test center (not shown) and may be configured to transfer various signals between the DUTs and the test center. The test center may be configured to generate various test signals for electrically testing the DUTs. The test signals may be transferred to the DUTs by the test head 100. The response signals may be generated from the DUTs in response to the testing signals and the response signals may be transferred to the test center by the test head 100. The response signals may be analyzed and evaluated in the test center for determining any functional defects of the devices.

The DUT may be individually inserted into the socket of the test socket 110 and may be electrically connected to the test head 100 that may be connected to the test center. Thus, the DUT may be electrically connected to the test center via the test head 100. For example, the test socket 110 may include a socket board 112 and multiple sockets 114 on the socket board 112. Each DUT may be inserted into a corresponding one of the sockets 114. Thus, the internal electrical circuit of the test head 100 may be connected to the DUT by the corresponding socket 114.

Thus, the testing signals may be transferred to the DUT from the test center via the socket 114 of the test head 100 and the response signals may be transferred to the test center from the DUT via the socket 114 of the test head 100.

The test center and the test handler 1000 may be systematically controlled by a central controller (not shown) in such a way that the testing signals and the response signals may be properly generated and transferred between the test center and the DUT. The evaluation of the response signals may be performed in the test center or the test head 100, so that the DUTs may be sorted into the good devices SD1 and the bad devices SD2.

The contact structure 300 may be positioned in the third chamber 230 and may push the DUTs in the test tray TT toward the corresponding socket 114 in such a way that the DUTs in the test tray TT may make contact with the sockets 114 of test socket 110. Thus, the DUTs may make contact with the sockets 114, respectively, by the contact structure 300.

In this embodiment, the test tray TT may be moved to a vertical state from a horizontal state by the vertical changer and then may be loaded into the first chamber 210 from the tray loader 400. Thus, the test socket 110 and the test tray TT may vertically face each other in a second direction y corresponding to a height of the test chamber 200, as shown in FIG. 2.

Particularly, a lead wire (not shown) of the DUT may extend toward the socket 114 and the contact structure 300 may face an upper face of the DUT. Thus, when the contact structure 300 may apply a force to the upper face of the DUT along a third direction z, the DUT may be pushed in the test tray TT and thus the lead wire may be inserted into the socket 114. Therefore, the lead wire of the DUT may make contact with the internal electrical circuit of the test head 100.

For example, the contact structure 300 may include a base body 310 configured to be driven by a driving unit 390, a first pusher assembly 320 arranged on the base body 310 and configured to push the DUT at a first temperature and a second pusher assembly 330 arranged on the base body 310 and configured to push the DUT at a second temperature higher than the first temperature. The first pusher assembly 320 may be configured to cool the DUT down to the first temperature and the second pusher assembly 330 may heat the DUT up to the second temperature. The first and the second pusher assemblies 320 and 330 may be individually arranged on the base body 310.

The base body 310 may include a first surface 311 facing the test tray TT and a second surface 312 opposite to the first surface 311. Multiple first and the second pusher assemblies 320 and 330 may be arranged on the first surface 311. The driving unit 390 may be arranged on the second surface 312 of the base body 310. The driving unit 390 may be configured to move the base body 310 in a first direction x along which the test tray TT may move and may drive the first and the second pusher assemblies 320 and 330 to move in the third direction z.

Hereinafter, the first direction x denotes a direction along which the test tray TT may move and the second direction y denotes a height direction of the test chamber 200. The third direction z denotes a direction along which the DUT is pushed to thereby make contact with the socket 114.

The shapes and configurations of the base body 310 may be variously modified as long as the base body 310 may have sufficient strength and stiffness for the base plate to which the first and the second pusher assemblies 320 and 330 and the driving unit 390 may be stably installed.

In addition, the size of the base body 310 may be varied according to the structures and the arrangements of the first and the second pusher assemblies 320 and 330. For example, the base plate 310 may include a match plate or a match frame matching with the shape and configuration of the test tray TT receiving multiple DUTs.

The driving unit 390 may include a driving board 391 and a driving operator (not shown) coupled to the driving board 391. The driving unit 390 may be configured to move the base body 310 in the first direction x in such a way that the base body 310 may be arranged to face the test tray TT in the third chamber 230. When the base body 310 may be located at a correct position facing the test tray TT, the driving unit 390 may be configured to drive the first and the second pusher assemblies 320 and 330 to move in the third direction z and thus a force may be applied to the DUT in the test tray TT toward the test socket 110. Accordingly, the DUTs in the test tray TT may make contact with the sockets 114 in the test socket 110, respectively.

The first and the second pusher assemblies 320 and 330 may be individually arranged on the base body 310 and may be configured to individually push the DUTs in the test tray TT. The first pusher assembly 320 may include a cooler for cooling the DUT down to the first temperature and the second pusher assembly 330 may include a heater for heating the DUT up to the second temperature.

In this embodiment, the first and the second pusher assemblies 320 and 330 may be provided in correspondence to every insert I of the test tray TT, so that the DUTs in the same insert I may be simultaneously pushed by the first and the second pusher assemblies 320 and 330. For example, four DUTs may be inserted into a single insert I of the test tray TT, and thus the first and the second pusher assemblies 320 and 330 may push four DUTs simultaneously.

Multiple inserts I may be provided with the test tray TT as an insert matrix and the first and the second pusher assemblies 320 and 330 may be arranged on the first surface 311 of the base body 310 as a pusher matrix in correspondence to the insert matrix. The first and the second pusher assemblies 320 and 330 may be arranged on the first surface 311 independently from each other, and thus the first and the second pusher assemblies 320 and 330 may push the DUTs in the test tray TT, respectively.

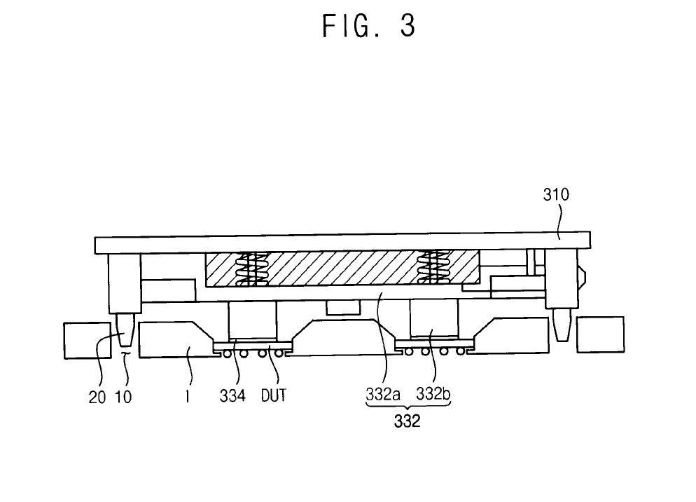

FIG. 3 is a cross-sectional view illustrating the DUT and the contact structure in FIG. 2 that makes contact with each other. FIG. 3 shows that the DUT may be pushed by the second pusher assembly 330. However, the DUT may also be pushed by the first pusher assembly 320 in the same way.

Referring to FIG. 3, the second pusher assembly 330 may interface with the insert I of the test tray TT and thus the DUTs in the insert I may be simultaneously pushed by a lead pusher 332b of the second pusher assembly 330. In this embodiment, joint protrusions 20 may be arranged around the first pusher assembly 320 and may be inserted into joint holes 10 that may be arranged around the insert I, so that the lead pushers 322b may automatically and correctly push the DUTs in the insert I, respectively.

The heater 334 may be arranged on each lead pusher 332b and may directly contact with each DUT in the insert I. Thus, the DUT may be configured to heat to the second temperature by thermal conduction with the heater 334.

Since four DUTs may be inserted into the insert I, four lead pushers 332b may be included in the second pusher assembly 330 and the heater 334 may be included with each of the lead pushers 332b. Therefore, the number of the heaters 334 and the lead pushers 332b may be varied according to the number of the DUT in the insert I.

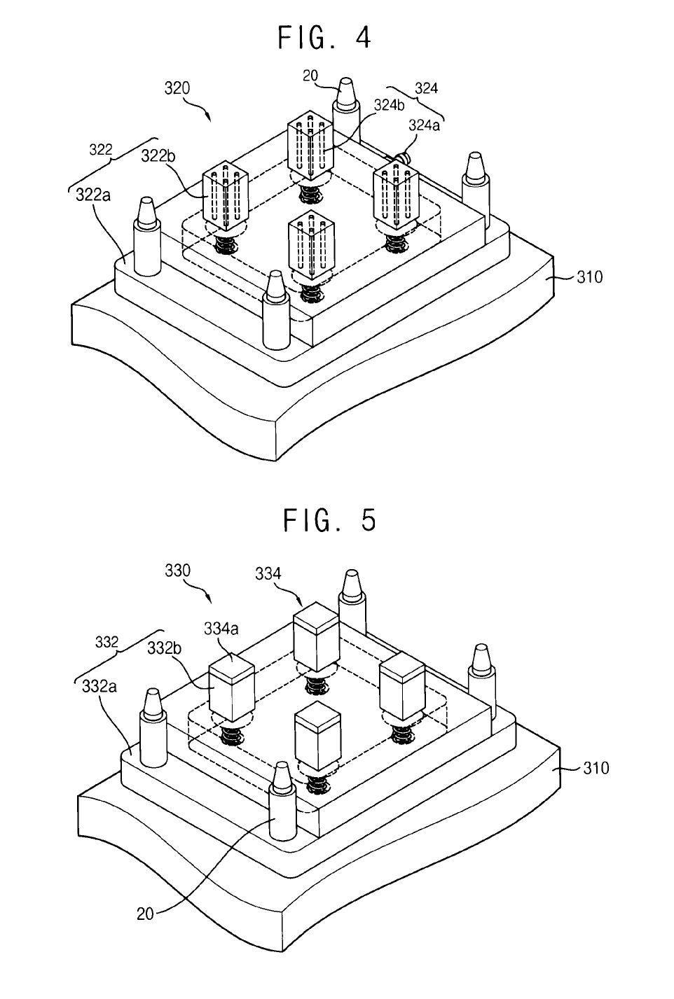

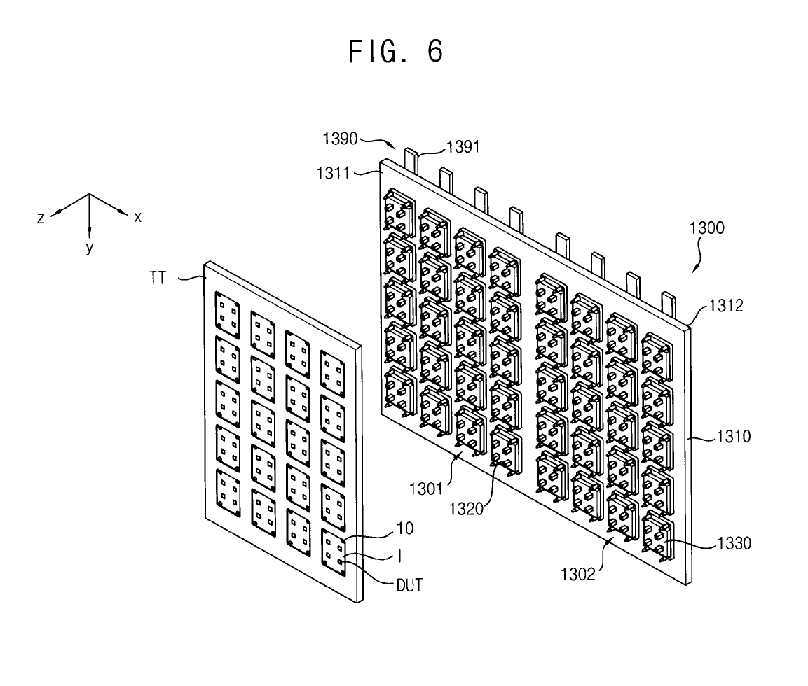

FIG. 4 is a perspective view illustrating the first pusher assembly of the contact structure shown in FIG. 2 and FIG. 5 is a perspective view illustrating the second pusher assembly of the contact structure shown in FIG. 2.

Referring to FIGS. 4 and 5, the first pusher assembly 320 may include a first pusher 322, configured to make contact with the DUT and push the DUT toward the test socket 110, and a cooler 324 included with the first pusher 322 and configured to cool the DUT down to a lower temperature. In contrast, the second pusher assembly 330 may include a second pusher 332, configured to make contact with the DUT and push the DUT toward the test socket 110, and a heater 334 included with the second pusher 332 and configured to heat the DUT up to a higher temperature. In this embodiment, the cooler 324 may be configured to make contact with the DUT and absorb heat from the DUT by the thermal conduction and the heater 334 may be configured to also make contact with the DUT and transfer heat to the DUT by the thermal conduction.

The first pusher 322 may include a first pusher block 322a combined to the base body 310 and a first lead pusher 322b extending from the first pusher block 322a and configured to push the DUT.

The first pusher block 322a may be configured to correspond to the insert I, so that the insert I may be covered with the first pusher block 322a when the test tray TT makes contact with the contact structure 300. Multiple joint protrusions 20 may be arranged on the first pusher block 322a and may be configured to be inserted into the joint holes 10 of the insert I for alignment of the insert I and the first pusher block 322a.

The first lead pusher 322b may protrude from the first pusher block 322a and may be configured to make contact with each DUT in the insert I. The first lead pusher 322b may be configured to push the DUT toward the test socket 110 and thus the DUT may be inserted into the socket 114. In this embodiment, an end portion of the first lead pusher 322b may include a flat surface and may be configured such that the DUT may make uniform contact with the first lead pusher 322b.

For example, the cooler 324 may include a gas inlet 324a for supplying cooling gases into the first pusher block 322a and at least a branch line 324b for distributing the cooling gases into each of the first lead pusher 322b from the first pusher block 322a. The cooling gases may be supplied into the first pusher block 322a from an external gas reservoir (not shown) and then may be distributed into each of the first lead pusher 322b through the branch line 324b. Since the first lead pusher 322b may be configured to make contact with the DUT, the DUT may be cooled down by the cooling gases due to the thermal conduction between the DUT and the cooling gases.

The second pusher 332 may include a second pusher block 332a combined with the base body 310 and a second lead pusher 332b extending from the second pusher block 332a. The second lead pusher 332b may be configured to push the DUT.

The second pusher block 332a and the second lead pusher 332b may have substantially the same structures as the first pusher block 322a and the first lead pusher 322b, except for the heater 334 in place of the cooler 324. Thus, any detailed descriptions on the second pusher block 332a and the second lead pusher 332b will be omitted hereinafter.

For example, the heater 334 may include a heating plate 334a that may be positioned on an end portion of the second lead pusher 332b and may be configured to make contact with the DUT and a power cable (not shown) extending from the heating plate 334a through the second lead pusher 332b and configured to transfer an electrical power to the heating plate 334a from an external power source. The power cable may be connected to a power socket (not shown) of the base body 310. Since the heating plate 334a may be configured to make direct contact with the DUT, the DUT may be heated up by the heater 334 due to the thermal conduction of the joule heat.

While this embodiment discloses the cooling gases flowing into the first lead pusher 322b through the branch line 324b as the cooler 324 and the electrical heater making contact with the DUT as the heater 334, any other elements or structures would be utilized as the cooler 324 and the heater 334 as long as the DUT may be cooled down or heated up by the elements, whether by thermal conduction, radiation, or the like.

For example, a thermoelectric element may be utilized as the cooler 324 and a micro heater or a thermoelectric element may be utilized as the heater 334. Particularly, the thermoelectric element may be utilized as the cooler 324 (thermal absorber) or the heater 334 (thermal generator) just merely reversing the electrical currents to the thermoelectric element due to the Peltier effect. Thus, when the thermoelectric element may be utilized as the cooler 324 and the heater 334, the first and the second pusher assemblies 320 and 330 may have the same structures.

When the DUT may make contact with the socket 114 by the first pusher assembly 320, the DUT may be cooled down to the first temperature (relatively lower temperature) by the cooler 324 and then the electrical test may be performed to the DUT at the first temperature. That is, a cold test may be conducted to the DUT in the third chamber 230. When completing the cold test on the DUT, the DUT may become in contact with the socket 114 by the second pusher assembly 330 and then the DUT may be heated up to the second temperature (a relatively higher temperature) by the heater 334. The same electrical test may be performed on the DUT at the second temperature, so that a hot test may be conducted to the DUT in the third chamber 230. Therefore, the conversion time between the cold test and the hot test may be sufficiently shortened, thereby reducing the electrical test time to the semiconductor devices.

The first and the second pusher assemblies 320 and 330 may be arranged on the base body 310 in various configurations and structures, so that the contact structure 300 may be modified into various configurations according to the requirements of the test handler 1000 and the automatic test equipment (ATE) including the test handler 1000. Hereinafter, various modifications of the contact structure will be disclosed in detail.

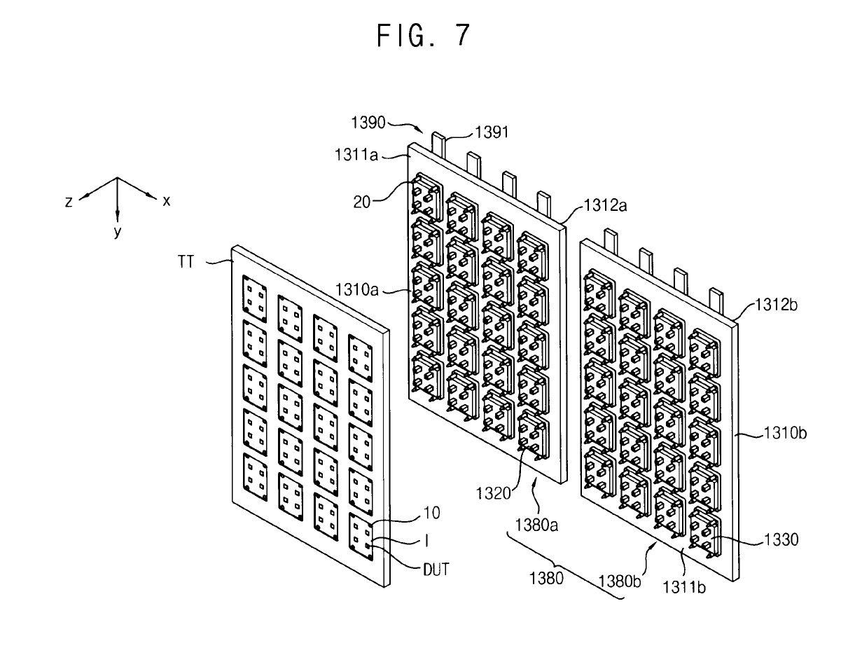

FIG. 6 is a perspective view illustrating a first modified example embodiment of the contact structure of the test handler shown in FIG. 1 according to an embodiment. Referring to FIG. 6, the first modified contact structure 1300 may include a single large-scaled base body 1310 having first and second portions 1301 and 1302 in such a configuration that multiple first pusher assembly 1320 may be arranged on the first portion 1301 and multiple second pusher assembly 1330 may be arranged on the second portion 1302.

In FIG. 6, the larger base body 1310 may have a similar structure as the base body 310 in FIG. 2, but with a larger size. The first and the second pusher assemblies 1320 and 1330 may have substantially the same structure as the first and the second pusher assemblies 320 and 330 in FIGS. 4 and 5. Thus, any further detailed descriptions on the base body 1310 and the first and the second pusher assemblies 1320 and 1330 will be omitted.

Each of the first and the second portions 1301 and 1302 may have a size corresponding to the test tray TT. When the first portion 1301 of the base body 1310 may be arranged to face the test tray TT, the DUT may make contact with the first pusher assembly 1320 and the cold test may be performed to the DUT. In addition, when the second portion 1302 of the base body 1310 may be arranged to face the test tray TT, the DUT may make contact with the second pusher assembly 1330 and the hot test may be performed to the DUT.

For example, after completing the cold test to the DUT, the test tray TT may move along the first direction x and may be arranged to face the second portion 1302 and then the hot test may be performed to the DUT. In such a case, the test head 100 may also include a pair of first and second test sockets for performing the cold test and the hot test, respectively. In another embodiment, after completing the cold test to the DUT, the base body 1310 may move reversely along the first direction x and then the hot test may be performed to the DUT.

A driving unit 1390, arranged on a second surface 1312 of the body 1310, may be configured to drive the base body 1310 to move along the first direction x. For example, the driving unit 1390 may include a pusher driver (not shown) for driving the lead pusher to move toward the DUT in the test tray TT and an aligning driver (not shown) for driving the base body 1310 along the first direction x to face the test tray TT.

Since the DUT may be cooled down in the cold test by the cooler in the first pusher assembly 1320 and may be heated up in the hot test by the heater in the second pusher assembly 1330, the hot test and the cold test may be performed by using a respective heat transfer member, to thereby sufficiently reduce the conversation time of the temperatures between the cold test and the hot test to the DUT.

Therefore, after completing the cold test, the DUT may contact with the second pusher assembly in place of the first pusher assembly having the heater, so that the hot test may be initiated with a reduced time between the cold test and the hot test.

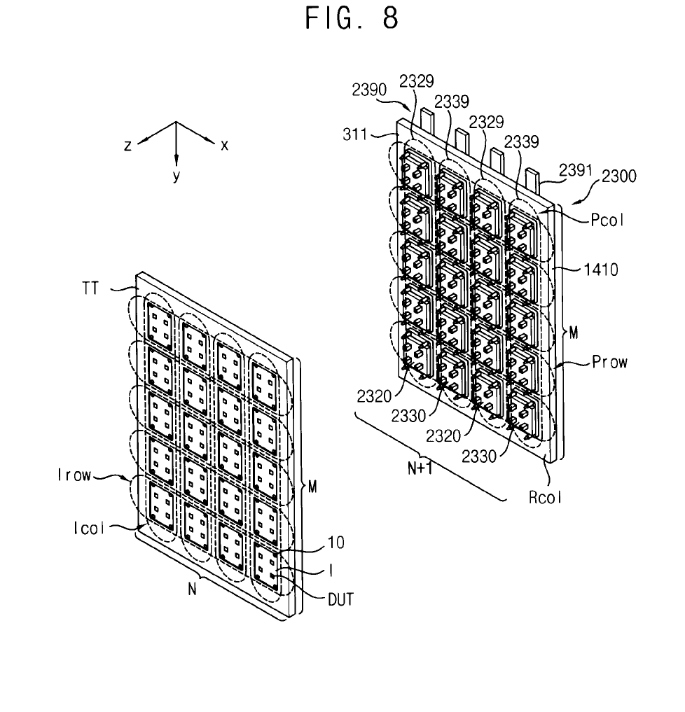

FIG. 7 is a perspective view illustrating a modification of the first modified example of the contact structure shown in FIG. 6 according to an embodiment. The modification of the first modified contact structure in FIG. 7 has substantially the same structures as the first modified contact structure 1300, except that the base body 1310 is separated into two pieces, so that the same reference numerals in FIG. 7 denote the same elements in FIG. 6 and any detailed descriptions on the same elements will be omitted hereinafter.

Referring to FIG. 7, the modification 1380 of the first modified contact structure 1300 may include a first contact section 1380a having a first match plate 1310a and multiple first pusher assemblies 1320 and a second contact section 1380b having a second match plate 1310b and multiple second pusher assemblies 1330. The large-scaled base body 1310 of the first modified contact structure 1300 may be separated into the first and the second match plates 1310a and 1310b matching with the test tray TT, respectively. For example, the first and second portions 1301 and 1302 of the large-scaled base body 1310 may be separated into the first and the second match plates 1310a and 1310b.

The first pusher assemblies 1320 may be arranged on a first surface 1311a of the first match plate 1310a and the cooler may be provided with each of the first pusher assemblies 1320, so that the first contact section 1380a may push the DUTs in the test tray TT for the cold test. The second pusher assemblies 1330 may be arranged on a first surface 1311b of the second match plate 1310b and the heater may be provided with each of the second pusher assemblies 1330, so that the second contact section 1380b may push the DUTs in the test tray TT toward the test socket 110 for the hot test.

In this embodiment, the first and the second contact sections 1380a and 1380b may be individually positioned in the test chamber 200 and thus the cold test and the hot test may be individually performed by using the first and second contact sections 1380a and 1380b. Accordingly, the temperature conversion time between the cold test and the hot test may be sufficiently reduced.

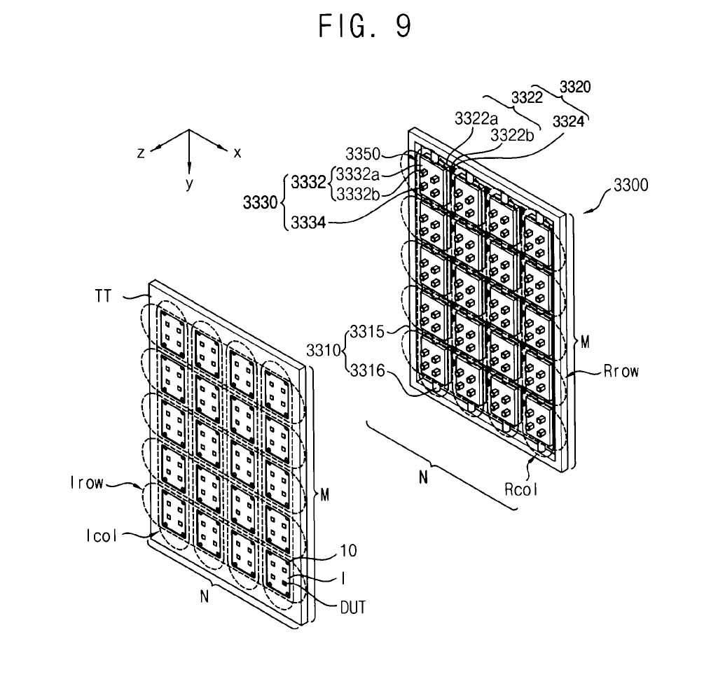

FIG. 8 is a perspective view illustrating a second modified example of the contact structure of the test handler shown in FIG. 1 according to an embodiment. In FIG. 8, the second modified contact structure may have a similar structure as the contact structure 300, except that the first and second pusher assemblies alternately arranged in a matrix shape. Thus, any further detailed descriptions on the base body and the first and the second pusher assemblies will be omitted.

Referring to FIG. 8, the second modified contact structure 2300 may include a base body 2310 and the first and the second pusher assemblies 2320 and 2330 arranged on the base body in a matrix shape. A cooler may be provided with the first pusher assembly 2320 and a heater may be provided with the second pusher assembly 2330. Particularly, the first pusher assembly 2320 and the second pusher assembly may be alternately arranged on the base body 2310 along the first direction x. A series of the first pusher assemblies 2320 along the second direction y may be configured to a first pusher column 2329 and a series of the second pusher assemblies 2330 along the second direction y may be configured to a second pusher column 2339. Thus, the first pusher column 2329 and the second pusher column 2339 may be alternately arranged on the base body 2310 along the first direction x.

For example, the test tray TT may include N (N is an integer number over 1) insert columns Icol that may be arranged on the test tray TT along the first direction x and M (M is an integer number over 1) insert rows Irow that may be arranged on the test tray TT along the second direction y, so that multiple inserts I may be arranged into an M×N matrix and multiple DUTs may be inserted into the M×N insert matrix. In the present example embodiment, since 4 DUTs may be received in a single insert I, M×N×4 DUTs may be received in the test tray TT.

Thus, multiple first pusher assemblies 2320 may be arranged in the second direction y to correspond to each insert I of the insert column Icol, to thereby form the first pusher column 2329 configured into an M×1 matrix. In the same way, multiple second pusher assemblies 2330 may be arranged in the second direction y to correspond to each insert I of the insert column Icol, to thereby form the second pusher column 2339 configured into an M×1 matrix.

The first pusher column 2329 and the second pusher column 2339 may be alternately arranged on the base body 2310 in the first direction x and the DUTs in the test tray may alternately contact with the first pusher column 2329 and the second pusher column 2339. Therefore, the cold test and the hot test may be alternately performed to the DUTs in the insert columns Icol along the first direction x. Particularly, the number of the first and the second pusher columns 2329 and 2339 may be one in excess of the number of the insert columns Icol. That is, when N insert columns Icol may be arranged on the test tray TT in the first direction x, (N+1) pusher columns 2329 and 2339 may be arranged on the base body 2310 in such a way that the first and the second pusher columns 2329 and 2339 may be alternate to each other along the first direction x.

Therefore, multiple DUTs may be received in the inserts I shaped into an M×N matrix, and multiple pusher assemblies may be arranged on the base body 2310 as an M×(N+1) pusher matrix in such a configuration that the first pusher assemblies 2320 and the second pusher assemblies 2330 may be alternately arranged in the first direction x along which the test tray TT may move in the test chamber 200.

That is, multiple inserts I may be arranged into the M×N matrix having M insert rows Irow and N insert columns Icol in the test tray TT and multiple first and the second pusher assemblies may be arranged on the base body 2310 into the M×(N+1) pusher matrix having M pusher rows Prow and (N+1) pusher columns Pcol in such a way that the first pusher column 2329 and the second pusher column 2339 may be alternately arranged along the first direction x. In such a case, the pusher assemblies in the pusher row Prow may correspond to the inserts I in the insert row how on a one-to-one basis.

The M×(N+1) pusher matrix may be divided into a first M×N sub-pusher matrix having 1^{St} column to N^{th} column and a second M×N sub-pusher matrix having 2^{nd} column to (N+1)^{th} column. The pusher assemblies of the first sub-pusher matrix may make contact with the DUTs in the M×N matrix-shaped inserts I and a first electrical test process may be performed to the DUTs. Thus, the cold and the hot tests may be simultaneously performed on alternate DUTs in the test tray TT in such a way that the DUTs in odd-numbered insert columns Icol may undergo the cold test and the DUTs in even-numbered insert columns Icol may undergo the hot test. After completing the first electrical test to the DUTs, the test tray TT may move in the first direction x, and thus the pusher assemblies of the second sub-pusher matrix may make contact with the DUTs in the M×N matrix-shaped inserts I. Then, a second electrical test process may be performed to the DUTs in the test tray TT in such a way that the DUTs in odd-numbered insert columns Icol may undergo the hot test and the DUTs in even-numbered insert columns Icol may undergo the cold test.

Therefore, the DUT experiencing the cold test in the first electrical test process may undergo the hot test in the second electrical test process and the DUT experiencing the hot test in the first electrical test process may undergo the cold test in the second electrical test process. That is, the DUT may undergo the cold test and the hot test in the test chamber 200 without a reduced time or no time lost between the cold test and the hot test.

Since the cooler of the first pusher assembly 2320 may be ready just for the cold test and the heater of the second pusher assembly 2330 may be ready just for the hot test, the DUT may undergo the cold test and the hot test in a sufficient time interval. That is, the conversion time between the cold test and the hot test may be sufficiently reduced by the second modified contact structure 2300.

That is, the cold test may be performed on the hot-tested DUT without a substantial time loss by using the second pusher assembly and the hot test may be performed on the cold-tested DUT without a substantial time loss by using the first pusher assembly, thereby reducing the time interval between the cold test and the hot test.

Although using N+1 columns has been used as an example, in other embodiments, M+1 rows and N columns may be used. The pusher assemblies of the M+1 rows may alternate between the first pusher assembly 2320 and the second pusher assembly 2330. Accordingly, between tests, the second modified contact structure 2300 may be moved in the y direction such that in a subsequent test, the different pusher assembly contacts the DUTs.

Moreover, although an alternating arrangement of first pusher assemblies 2320 and second pusher assemblies 2330 has been used as an example, in other embodiments, the arrangement of the pusher assemblies may take other forms. Any arrangement of pusher assemblies may be used such that in a first test, the DUTs are tested with a corresponding first one of the first pusher assemblies 2320 and second pusher assemblies 2330 and in a second test, the second modified contact structure 2300 is moved such that the DUTs are tested with the other pusher assembly of the first pusher assemblies 2320 and second pusher assemblies 2330.

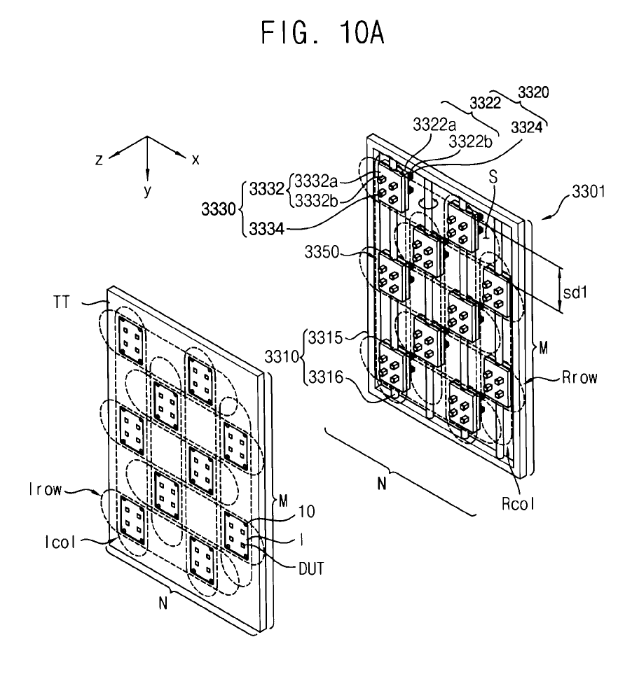

FIG. 9 is a perspective view illustrating a third modified example of the contact structure of the test handler shown in FIG. 1 according to an embodiment. Referring to FIG. 9, the third modified contact structure 3300 may include a base body 3310 having a match frame 3315 that may match with the test tray TT and multiple rods 3316 that may be installed to the match frame 3315, multiple rotators 3350 combined to the rod 3316 in correspondence to the inserts I of the test tray TT, respectively, and first and second pusher assemblies 3320 and 3330 combined to the rotators 3350.

For example, the rotator 3350 may be shaped into a plate that may be rotatably combined to the rod 3316 and have first and second surfaces opposite to each other. The first pusher assemblies 3320 may be arranged on the first surface of the rotatable plate and the cooler may be provided with each of the first pusher assemblies 3320. The second pusher assemblies 3330 may be arranged on the second surface of the rotatable plate and the heater may be provided with each of the second pusher assemblies 3330. Therefore, the first and the second pusher assemblies may be alternately contact with the DUTs in the test tray TT just by rotation of the plate-shaped rotator 3350.

The first and the second pusher assemblies 3320 and 3330 may have substantially the same structures as the first and the second pusher assemblies 320 and 330 as described in detail with reference to FIGS. 4 and 5.

That is, the first pusher assembly 3320 may include a first pusher 3322 having a first pusher block 3322a and a first lead pusher 3322b and a cooler 3324 having a gas inlet (not shown) and a branch line (not shown). In the same way, the second pusher assembly 3330 may include a second pusher 3332 having a second pusher block 3332a and a second lead pusher 3332b and a heater 3334.

In this embodiment, the gas inlet may be provided with the first pusher block 3322a and be configured to communicate through the rod 3316 and the branch line may penetrate through the first pusher block 3322a and may be connected to each of the first lead pushers 3322b that may be arranged on the first pusher block 3322a. Electrical power may be applied to the heater 3334 through a power cable that may be connected to an external power source via the second pusher block 3332a and the rod 3316.

For example, the rotator 3350 may include a bearing structure that may be combined to the first and the second pusher blocks 3322a and 3332a.

The driving unit (not shown) may be combined to the base body 3310 and may drive the rotator 3350 to rotate and the first and the second pusher assemblies to move toward the test tray TT.

Multiple inserts I may be arranged into an M×N matrix having M insert rows Irow and N insert columns Icol in the test tray TT, thus multiple DUTs may be received in the M×N matrix type inserts I. Multiple rotators 3350 may be combined to the each of the rods 3316 in such a configuration that the rotator 3350 may be arranged in correspondence to the insert I, so that the rotators 3350 may be arranged into an M×N rotator matrix having N rotator columns Rcol corresponding to the insert columns Icol, respectively, and M rotator rows Rrow corresponding to the insert rows Irow, respectively.

The pusher assemblies on the neighboring rotators 3350 may collide with each other when the rotator 3350 may rotate with respect to the rod 3316. For that reason, the rods may be spaced apart from each other along the first direction x by a gap distance greater than a total length of the first and the second pushers 3322 and 3332.

In such a case, the inserts I may also be spaced apart from each other in the test tray TT along the first direction x in correspondence to the gap distance of the rods 3316 and the rotators 3350. In the same way, the sockets 114 of the test socket 110 may be grouped in correspondence to the inserts I and the groups of the sockets 114 may be spaced apart from each other along the first direction x in correspondence to the gap distance of the rods 3316 and the rotators 3350.

Therefore, the DUTs received in a M×N insert matrix of the test tray TT may make contact with the first pushers or the second pushers that may be combined to an M×N rotator matrix of the third modified contact structure 3300, so that the cold test and the hot test may be easily conducted to the DUT in the test chamber 200 just by rotating the rotators 3350.

That is, the first pusher assembly 3320 for the cold test may be simply exchanged with the second pusher assembly 3330 for the hot test just by rotating the rotators 3350, thus the cold test to the DUT may be converted to the hot test to the same DUT at a sufficiently minimized temperature conversion time.

Since the cooler combined to the first pusher 3322 may be prepared only for cooling the DUT and the heater combined to the second pusher 3332 may be prepared only for heating the DUT, no time interval for temperature conversion between the first temperature for the cold test and the second temperature for the hot test may be required, which sufficiently reduce the overall test time of the DUTs.

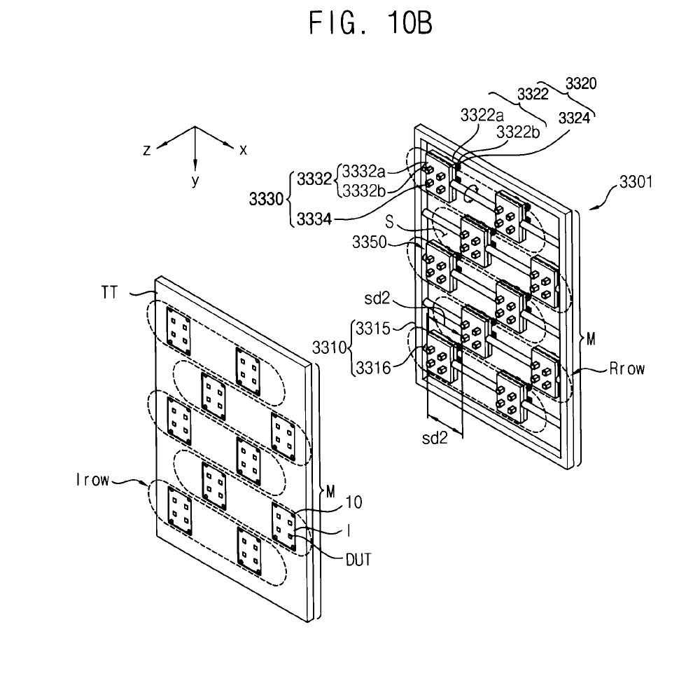

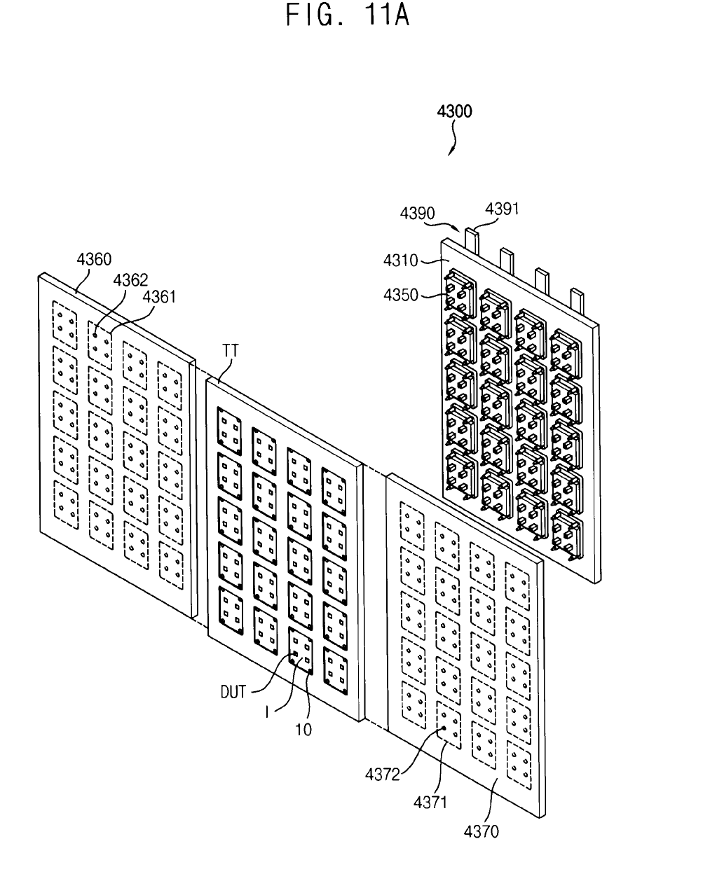

FIG. 10A is a perspective view illustrating a first modification of the third modified contact structure shown in FIG. 9 according to an embodiment. In FIG. 10A, the first modification 3301 of the third modified contact structure 3300 has substantially the same structures as the third modified contact structure 3300, except for the modified rotator matrix described hereinafter. In addition, the test tray TT also has modified insert matrix corresponding to the modified rotator matrix. Thus, the first modification 3301 of the third modified contact structure 3300 will be described in detail based on the modified rotator matrix and the modified insert matrix hereinafter.

Referring to FIG. 10A, the rod 3316 may be provided with the match frame 3315 along with the insert column Icol of the test tray TT and the rotators 3350 in the first modification 3301 may be spaced apart from each other along the rod 3316 more than the rotators 3350 in the third modified contact structure 3300 and even-numbered rotator columns Rcol may be shifted downwards along the rod 3316 by a first shifting distance sd1.

For example, the even-numbered rotator columns Rcol may be shifted from the top portion of the match frame 3315 by the first shifting distance sd1 along the second direction y without shifting odd-numbered rotator columns Rcol, so that odd-numbered rotator columns Rcol may be higher than the even-numbered rotator columns Rcol along the rod 3316. In this embodiment, the first shifting distance sd1 may be substantially equal to a gap distance between the neighboring rotators 3350 in the rotator column Rcol, so that the rotators 3350 may be alternately arranged in the base body 3310 in both of the first and the second directions x and y.

Therefore, an inter-space S may be provided between neighboring rotators 3350 in the same rotator row Rrow and may function as a rotation space for the first and second pushers 3322 and 3332 that may be combined to the neighboring rotators 3350. Thus, the first and the second pushers 3322 and 3332 combined to the neighboring rotators 3350 may be sufficiently prevented from colliding with each other when the neighboring rotators 3350 may be rotated with respect to the rod 3316.

In such a case, the rods 3316 may be spaced apart from each other along the first direction x by a rod gap corresponding to the total length of the first and the second pushers 3322 and 3332. The number of the rods 3316 may be varied according to the number of the DUTs in the electrical test process in the test chamber 200.

Further, the inserts I may also be spaced apart from each other in the test tray TT along the first direction x in correspondence to the rod gap of the rods 3316 and the rotators 3350. In the same way, the sockets 114 of the test socket 110 may be grouped in correspondence to the inserts I and the groups of the sockets 114 may be spaced apart from each other along the first direction x in correspondence to the rod gap of the rods 3316 and the rotators 3350.

FIG. 10B is a perspective view illustrating a second modification of the third modified contact structure shown in FIG. 9 according to an embodiment. In FIG. 10B, the second modification 3302 of the third modified contact structure 3300 has substantially the same structures as the first modification 3301 having the modified rotator matrix, except that the rod may extend in the first direction x, not in the second direction y. The test tray TT has the same modified insert matrix corresponding to the modified rotator matrix. Thus, the second modification 3302 of the third modified contact structure 3300 will be described in detail based on the rod extending along the first direction x as well as the modified rotator matrix and the modified insert matrix.

Referring to FIG. 10B, the rod 3316 may be provided with the match frame 3315 along with the insert row how of the test tray TT and the rotators 3350 in the second modification 3302 may be spaced apart from each other along the rod 3316 more than the rotators 3350 in the third modified contact structure 3300 and even-numbered rotator rows Rrow may be shifted rightwards along the rod 3316 by a second shifting distance sd2.

For example, the even-numbered rotator rows Rrow may be shifted from the left portion of the match frame 3315 by the second shifting distance sd2 along the first direction x without shifting odd-numbered rotator rows Rrow, so that odd-numbered rotator rows Rrow may be closer to the left portion of the match frame 3315 than the even-numbered rotator rows Rrow along the rod 3316. In the present example embodiment, the second shifting distance sd2 may be substantially equal to a gap distance between the neighboring rotators 3350 in the rotator row Rrow, so that the rotators 3350 may be alternately arranged in the base body 3310 in both of the first and the second directions x and y.

Therefore, an inter-space S may be provided between neighboring rotators 3350 in the same rotator row Rrow and may function as a rotation space for the first and second pushers 3322 and 3332 that may be combined to the neighboring rotators 3350. Thus, the first and the second pushers 3322 and 3332 combined to the neighboring rotators 3350 may be sufficiently prevented from colliding with each other when the neighboring rotators 3350 may be rotated with respect to the rod 3316.

In such a case, the rods 3316 may be spaced apart from each other along the second direction y by a rod gap corresponding to the total length of the first and the second pushers 3322 and 3332. The number of the rods 3316 may be varied according to the number of the DUTs in the electrical test process in the test chamber 200.

Further, the inserts I may also be spaced apart from each other in the test tray TT along the second direction y in correspondence to the rod gap of the rods 3316 and the rotators 3350. In the same way, the sockets 114 of the test socket 110 may be grouped in correspondence to the inserts I and the groups of the sockets 114 may be spaced apart from each other along the second direction y in correspondence to the rod gap of the rods 3316 and the rotators 3350.

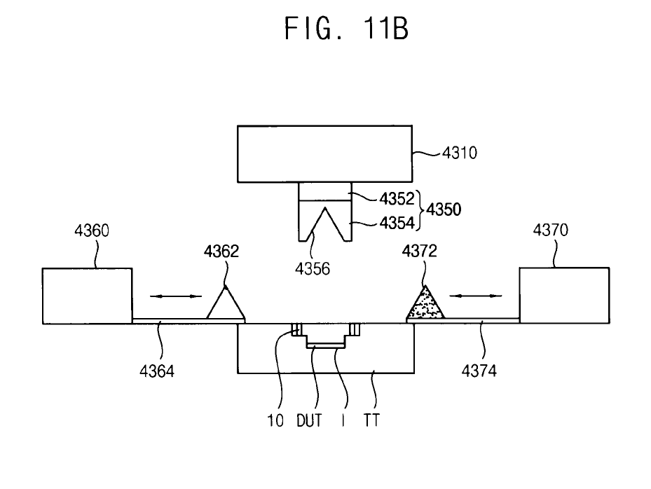

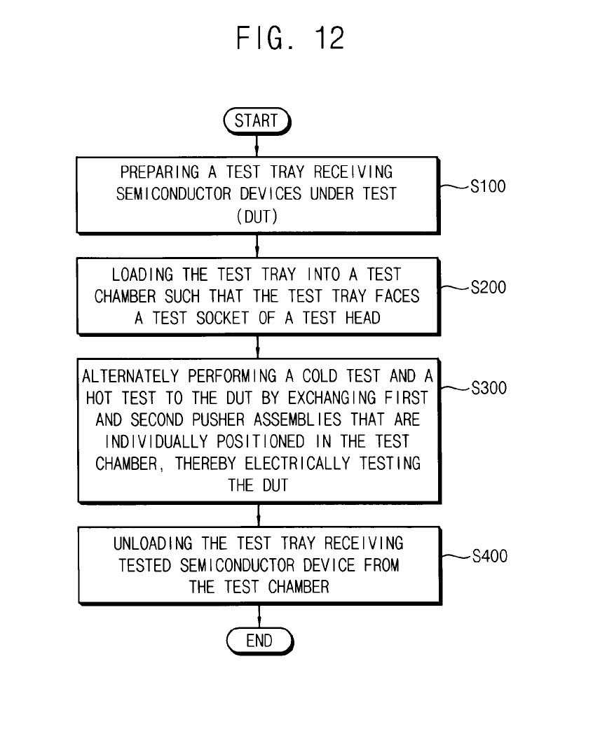

FIG. 11A is a perspective view illustrating a fourth modified example of the contact structure of the test handler shown in FIG. 1 according to an embodiment. FIG. 11B is a view illustrating an operation of the contact structure shown in FIG. 11A according to an embodiment. Referring to FIGS. 11A and 11B, the fourth modified contact structure 4300 may include a match plate 4310 matching with the test tray TT, multiple pushers 4350 arranged on the match plate 4310 in correspondence to the inserts I of the test tray TT to thereby push the DUTs in the inserts I, a cooling tip 4362 configured to be selectively combined to the pusher 4350 and cool the DUT and a heating tip 4372 configured to selectively combined to the pusher 4350 and heat the DUT.

Thus, the pusher 4350 and the cooling tip 4362 combined to the pusher 4350 may function as the first pusher assembly for the cold test and the pusher 4350 and the heating tip 4372 combined to the pusher 4350 may function as the second pusher assembly for the hot test. The cooling tip 4362 and the heating tip 4372 may make direct contact with the DUT and the DUT may be cooled down or heated up by the thermal conduction.

The pusher 4350 may include a pusher block 4352 combined to the match plate 4310 and a lead pusher 4354 protruding from the pusher block 4352 and configured to push the DUT toward the socket 114. A tip hold 4356 may be provided at an end portion of the lead pusher 4354 for receiving the cooling tip 4362 and the heating tip 4372.

The cooling tip 4362 may be standby at a first standby area under the first temperature for the cold test and the heating tip 4372 may be standby at a second standby area under the second temperature for the hot test. The first and the second standby area may be provided close to the test tray TT.

In this embodiment, the fourth modified contact structure may further include a cooling chamber 4360 for cooling the cooling tip 4362 down to the first temperature for the cold test and a heating chamber 4370 for heating the heating tip 4372 to the second temperature for the hot test.

The cooling chamber 4360 may include a first receiving plate 4364 on which multiple first holes 4361 may be arranged into a matrix in correspondence to multiple pusher 4350, respectively. Thus, the cooling tips 4362 may be individually received in the first holes 4361 of the first receiving plate 4364. In the same way, the heating chamber 4370 may include a second receiving plate 4374 on which multiple second holes 4371 may be arranged into a matrix in correspondence to multiple pusher units 4350, respectively. Thus, the heating tips 4372 may be individually received in the second holes 4371 of the second receiving plate 4374.

The cooling chamber 4360 may be configured to cool multiple cooling tips 4362 simultaneously to a lower temperature for the cold test. The heating chamber 4370 may be configured to heat multiple heating tips 4372 simultaneously to a higher temperature for the hot test.

For example, after the cold test to the DUT may be completed, the pushers 4350 combined with the cooling tips 4362 may be separated from the DUTs and may move to the first standby area in which the first receiving plate 4364 may be located. The first standby area may be provided around the test tray TT. Then, the cooling tips 4362 may be separated from the tip holder 4356 of the pushers 4350 and may be received into the first holes 4361 of the first receiving plate 4364. Since the pushers 4350 and the first holes 4361 may be arranged into the same matrix, the cooling tips 4362 may be received into the respective first holes 4361. Then, the first receiving plate 4364 may move into the cooling chamber 4360 and the cooling tips 4362 may be sufficiently cooled down to the lower temperature for another cold test.

When the cooling tips 4362 may be separated from the pushers 4350, the match plate 4310 may move to the second standby area in which the second receiving plate 4374 may be located. Multiple heating tips 4372 may be standby in the second holes 4371 of the second receiving plate 4374 under the second temperature for the hot test. The heating tips 4372 may be combined to the tip holders 4356 of the pushers 4350, respectively.

The pushers 4350 combined with the heating tips 4372 may move to the test tray TT and may make contact with the DUTs in the test tray TT, and then the hot test may be conducted to the DUTs.

Since the cooling tip 4362 and the heating tip 4372 may be individually provided at the first and the second temperatures, respectively, no temperature conversion time between the cold test and the hot test may be needed in the test chamber 200, which may sufficiently reduce an overall test time to the DUTs.

According to some embodiments of the contact structure and the test handler including the same, the first pusher assembly for the cold test and the second pusher assembly for the hot test may be individually provided in a single test chamber. The first pusher assembly may be standby under the first temperature for the cold test and the second pusher assembly may be standby under the second temperature of the hot test.

Accordingly, the cold test and the hot test may be converted to each other in the same test chamber just by exchanging the first and the second pusher assemblies with each other, so that no temperature conversion time may be needed between the cold test and the hot test. Thus, the overall test time to the DUTs may be sufficiently reduced in test chamber.

Hereinafter, the method of electrically testing DUTs by using the contact structure and the test handler will be described in detail.

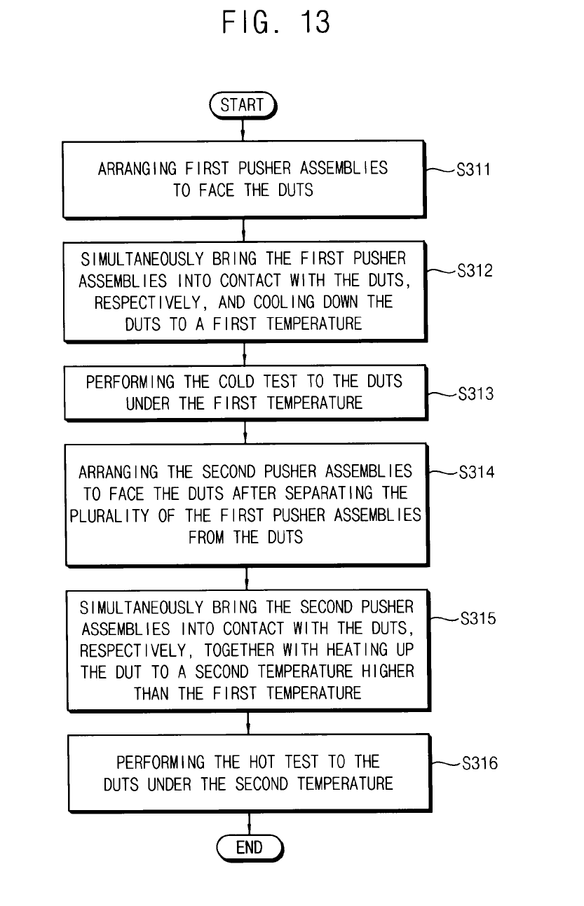

FIG. 12 is a flow chart showing processing steps for a method of electrically testing DUTs by using the test handler shown in FIG. 1 according to an embodiment. Referring to FIGS. 1 and 12, the test tray TT may be prepared in such a way that multiple inserts I may be provided with the test tray TT and at least one DUT may be received in each of the inserts I (step S100). In this embodiment, multiple DUTs may be received in the first user tray UT1 and the first user tray UT1 may be transferred to the test handler 1000. Then, the DUTs may be individually picked up from the user tray UT1 by the first picker P1 into the test tray TT of the tray loader 400.

Then, the test tray TT may be loaded into the test chamber 200 in such a way that the test tray TT may face the test socket 110 of the test head 100 and the DUTs may be arranged with sockets 114 of the test socket 110, respectively (step S200). The test tray TT may be changed into the vertical state from the horizontal state and may be arranged to face the test socket 110 by the transfer unit such as the transfer rail in the test chamber 200.

Thereafter, a cold test and a hot test may be alternately performed to the DUT by exchanging first and second pusher assemblies that may be individually positioned in the test chamber 200, thereby electrically testing the DUT (step S300). The first pusher assembly may push the DUT to the socket 114 and cool down the DUT for the cold test by a thermal conduction and the second pusher assembly may push the DUT to the socket 114 and heat up the DUT for the hot test by thermal conduction, radiation, or the like.

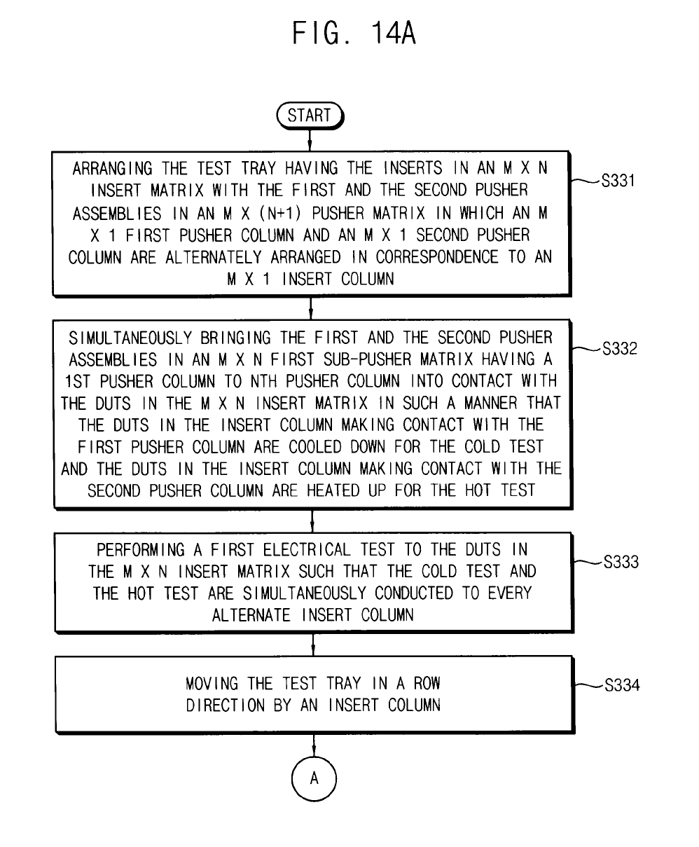

FIG. 13 is a flow chart showing the steps for alternately performing the cold test and the hot test by using the contact structure shown in FIG. 6 according to an embodiment.

Referring to FIGS. 1, 6 and 13, multiple first pusher assemblies 1320 may be arranged to face multiple DUTs (step S311). For example, the test tray TT may be moved by the driving unit 1390 in the test chamber 200 in such a way that the inserts I of the test tray may face the first pusher assemblies 1320, respectively.

Then, the first pusher assemblies 1320 may be moved toward the test tray TT by the driving unit 1390 and thus may be simultaneously brought into contact with the DUTs, respectively, cooling down the DUTs to the first temperature in such a manner that the DUTs are pushed into the sockets, respectively, under the first temperature (step S312). For example, the cooling gases may flow into the lead pushers of the first pusher assemblies 1320 for cooling down the DUTs and then the cold test to the DUTs may be performed under the first temperature (step S313). The testing signals may be applied to the DUTs under the first temperature and the responsive signals in response to the testing signals may be detected from the DUTs and analyzed in the test center.

After the cold test to the DUTs, multiple second pusher assemblies 1330 may be arranged to face the DUTs after separating the first pusher assemblies 1320 from the DUTs (step S314).

For example, the test tray TT may be moved by the transfer unit in such a way that the DUTs completing the cold test may face the second area 1302 of the base body 1310 in which the second pusher assemblies 1330 may be arranged. Otherwise, the base body 1310 may be moved by the driving unit 1390 in such a way that the second area 1302 may face the test tray TT. If the base body 1310 is separated into the independent first and second contact sections 1380a and 1380b as shown in FIG. 7, the second pusher assemblies 1330 may be arranged to face the DUTs by the relative movement of the first and the second match plates 1310a and 1310b with respect to the test tray TT.

Then, the second pusher assemblies 1330 may be moved toward the test tray TT by the driving unit 1390 and thus may be simultaneously brought into contact with the DUTs, respectively, and heated up to the DUTs to the second temperature in such a manner that the DUTs are pushed into the sockets, respectively, under the second temperature (step S315). For example, the electrical heater may heat the DUTs to the second temperature by a thermal conduction of the Joule's heat. Then the hot test to the DUTs may be performed under the second temperature (step S316). The testing signals may be applied to the DUTs under the second temperature and the responsive signals in response to the testing signals may be detected from the DUTs and analyzed in the test center.

Therefore, the cold test and the hot test to the same DUT may be more rapidly performed without temperature conversion time between the hot test the cold test, thereby reducing an overall electrical test time of the semiconductor devices.

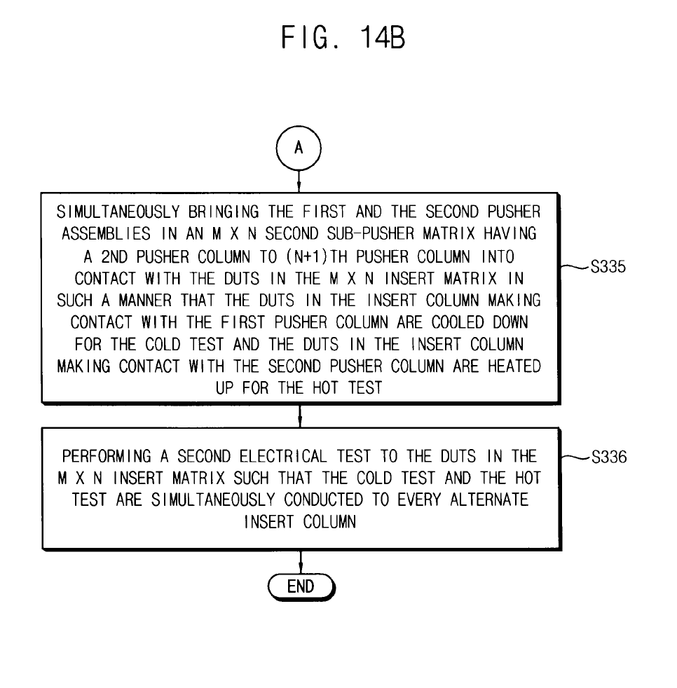

FIGS. 14A and 14B are a flow chart showing the steps for alternately performing the cold test and the hot test by using the contact structure shown in FIG. 8 according to some embodiments. Referring to FIGS. 1, 8, 14A and 14B, the test tray TT may be prepared to include multiple inserts I in an M×N insert matrix and the match plate 2300 corresponding to the test tray TT may be provided in the test chamber 200. The test tray TT may be arranged to face the first and the second pusher assemblies 2320 and 2330 that may be arranged on the match plate 2300 in the M×(N+1) pusher matrix in which the M×1 first pusher column 2329 and the M×1 second pusher column 2339 may be alternately arranged in correspondence to the M×1 insert column (step S331).

For example, multiple DUTs may be inserted in the M×N insert matrix of the test tray TT and the M×1 first and the second pusher columns 2329 and 2339 may be arranged in correspondence to the insert columns Icol, respectively. In this embodiment, (N+1) first and second pusher columns 2329 and 2339 may be arranged along the direction of the insert row how of the insert matrix in such a way that the first pusher columns 2329 and the second pusher columns 2339 may be alternately arranged with each other in the M×(N+1) pusher matrix.

Then, the M×(N+1) pusher matrix may be grouped into the first sub-pusher matrix having a 1^{st} pusher column to N^{th} pusher column and the first and the second pusher assemblies 2320 and 2330 in the M×N first sub-pusher matrix may be simultaneously brought into contact with the DUTs in the M×N insert matrix in such a manner that the DUTs in the M×1 insert column Icol making contact with the M×1 first pusher column 2329 may be cooled down to the first temperature for the cold test and the DUTs in the M×1 insert column Icol making contact with the M×1 second pusher column 2339 may be heated up to the second temperature for the hot test (step S332).

Then, a first electrical test may be performed to the DUTs in the M×N insert matrix in such a manner that the cold test and the hot test are simultaneously conducted to every alternate M×1 insert column Icol (step S333).

After completing the first electrical test to the DUTs, the test tray TT may be moved in a row direction by an M×1 insert column Icol (step S334). Then, the M×(N+1) pusher matrix may be grouped into the second sub-pusher matrix having the 2^{nd} pusher column to (N+1)^{th} pusher column and the first and the second pusher assemblies 2320 and 2330 in the M×N second sub-pusher matrix may be simultaneously brought into contact with the DUTs in the M×N insert matrix in such a manner that the DUTs in the M×1 insert column Icol making contact with the M×1 first pusher column 2329 may be cooled down to the first temperature for the cold test and the DUTs in the M×1 insert column Icol making contact with the M×1 second pusher column 2339 may be heated up to the second temperature for the hot test (step S335). Then, a second electrical test may be performed to the DUTs in the M×N insert matrix in such a manner that the cold test and the hot test are simultaneously conducted to every alternate M×1 insert column Icol (step S336).

That is, the cold test and the hot test may be simultaneously conducted on the DUTs in the 1^{st} to N^{th} insert columns Icol alternately by the insert column Icol in the first electrical test and the hot test and the cold test may be simultaneously conducted to the DUTs in the 1^{st} to N^{th} insert columns Icol alternately by the insert column Icol in the second electrical test.

Therefore, when the DUTs in the insert column may undergo the cold test in the first electrical test, the hot test may be conducted to the DUTs in the same insert column in the second electrical test. In the same way, when the DUTs in the insert column may undergo the hot test in the first electrical test, the cold test may be conducted to the DUTs in the same insert column in the second electrical test.

Accordingly, the DUTs in the same insert column Icol may be simply converted between the cold test mode and the hot test mode just by a shift of the test tray TT by the insert column Icol without substantial temperature conversion time between the cold test and the hot test in the same test chamber, thereby reducing the overall electrical test time to the DUTs.

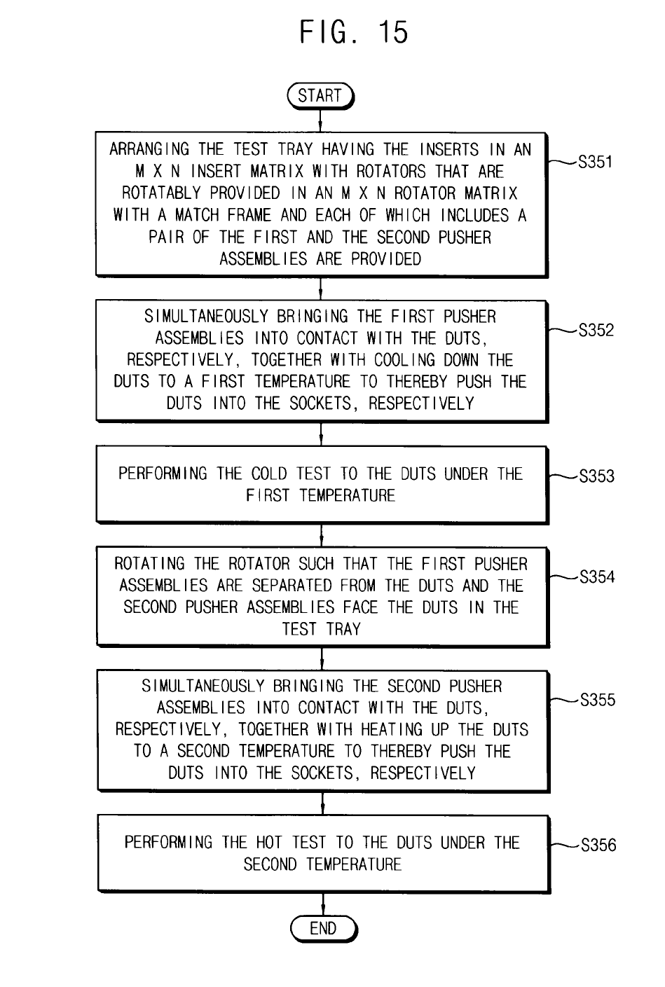

FIG. 15 is a flow chart showing the steps for alternately performing the cold test and the hot test by using the contact structure shown in FIG. 9 according to an embodiment.

Referring to FIGS. 1, 9 and 15, the test tray TT may be prepared to include multiple inserts I in an M×N insert matrix and the match frame 3315 corresponding to the test tray TT and multiple rods 3316 crossing the match frame 3315 may be provided in the test chamber 200. Multiple rotators 3350 may be combined to the rods 3316 in the M×N rotator matrix in correspondence to the M×N insert matrix of the test tray. The test tray TT may be arranged by the transfer unit in the test chamber in such a way that the inserts I in the insert matrix may face the rotator 3350 in the rotator matrix and a pair of the first and the second pusher assemblies 3320 and 3330 may be provided with each of the rotators 3350 (step S351).

Then, the first pusher assemblies 3320 may be simultaneously brought into contact with the DUTs in the insert column Icol, respectively, together with cooling down the DUTs to the first temperature such that the DUTs are pushed into the sockets, respectively, under the first temperature (step S352). The cold test may be performed to the DUTs under the first temperature (step S353).

When completing the cold test to the DUTs, the rotator 3350 may be rotated in such a way that the first pusher assemblies 3320 mat be separated from the DUTs and the second pusher assemblies 3330 may face the DUTs in the same insert column Icol of the test tray TT (step S354).

Then, the second pusher assemblies 3330 may be simultaneously brought into contact with the DUTs in the insert column Icol, respectively, together with heating up the DUTs to the second temperature such that the DUTs are pushed into the sockets, respectively, under the second temperature (step S355). The hot test may be performed to the DUTs under the second temperature (step S356).

Accordingly, the DUTs in the same insert column Icol may be simply converted between the cold test mode and the hot test mode just by a rotation of the rotator of the contact structure 3300 without substantial temperature conversion time between the cold test and the hot test in the same test chamber, thereby reducing the overall electrical test time to the DUTs.

Referring again to FIG. 12, after completing the electrical test to the DUTs, the test tray TT receiving the tested device TD may be unloaded from the test chamber (step S400). When completing the electrical test to the DUTs in the test tray TT, the test tray TT receiving multiple tested devices TD may be unloaded from the test chamber 200 by the tray unloader 500 and the tested devices TD may be sorted into good devices SD1 and bad devices SD2 in the sorter 600. The sorted devices SD may be picked up from the sorting table 610 by the second picker P2 and then may be transferred into the second user tray UT2. Thus, multiple sorted devices SD may be received into the second user tray UT2 and multiple second user tray UT2 may be stacked in the second stacker 800.

According to the example embodiments of the contact structure and the test handler including the same, the first pusher assembly for the cold test and the second pusher assembly for the hot test may be individually arranged in the same test chamber. In such a configuration, the first pusher assembly may be controlled to have the first temperature for the cold test and the second pusher assembly may be controlled to have the second temperature for the hot test. Thus, the first and the second pusher assemblies may be brought into contact with the DUTs under the first temperature for the cold test and the second temperature for the hot test, respectively.

As a result, changing from the cold test to the hot test on the same DUT may be easily performed just by interchanging the first and the second pusher assemblies without substantial temperature conversion time in the same test chamber, thereby sufficiently reducing an overall electrical test time to the DUT.

Embodiments of the test handler may be applied to various electrical test systems for testing electrical characteristics of electronic devices including integrated circuit chips and fine circuit devices.

An embodiment may include a contact structure in which a conversion time between a hot test and a cold test is reduced, shortening the test time and a test handler having the improved contact structure.

Some embodiments include a contact structure in which a first pusher assembly for the hot test and a second pusher assembly for a cold test to thereby reduce the conversion time between the cold test and the hot test.

Other embodiments include a test handler including the above contact structure.

Still other embodiments include a method of testing semiconductor devices by using the above test handler.

According to some embodiments, the contact structure may include a base body driven by a driving unit, at least a first pusher assembly arranged on the base body and making contact with the device under test (DUT), thereby pushing and cooling the DUT, and at least a second pusher assembly arranged on the base body individually from the first pusher assembly and making contact with DUT, thereby pushing and heating the DUT.

For example, the base body may include a plate, and multiple first pusher assemblies may be arranged on a first portion of the plate matching with a test tray receiving multiple DUTs and multiple second pusher assemblies may be arrange on a second portion of the plate matching with the test tray.

For example, the first and the second portions of the base body may be separated into first and second match plates that may be independent from each other and have a shape corresponding to the test tray, so that the first match plate and the plurality of the first pusher assemblies thereon may be provided as a first contact section for a cold test to the DUTs and the second match plate and the plurality of the second pusher assemblies thereon may be provided as a second contact section for a hot test to the DUTs independently from the first contact section.

For example, multiple DUTs may be received in multiple inserts of a test tray in such a configuration that the inserts may be arranged in an M×N insert matrix having N (N is an integer number over 1) insert columns M (M is an integer number over 1) insert rows, and multiple first and the second pusher assemblies may be arranged on the base body in an M×(N+1) pusher matrix in which an M×1 first pusher column, which denotes multiple first pusher assemblies that is arranged in series on the base body in correspondence to multiple inserts in the insert column, and an M×1 second pusher column, which denotes multiple second pusher assemblies that may be arranged in series in correspondence to multiple inserts in the insert column, may be alternately arranged on the base body.

For example, the base body may include a match frame matching with a test tray receiving multiple DUTs, multiple rods installed to the match frame and multiple rotators combined to each rod and having first and second surfaces opposite to each other in such a configuration that the first pusher assembly may be combined to the first surface and the second pusher assembly may be combined to the second surface, thus the first and the second pusher assemblies may be alternately brought into contact with the DUT by rotation of the rotator.

For example, the DUTs may be received in multiple inserts of the test tray in such a configuration that the inserts may be arranged in an M×N insert matrix having N (N is an integer number over 1) insert columns and M (M is an integer number over 1) insert rows, and the rotators may be arranged in an M×N rotator matrix having N rotator columns corresponding to the insert columns, respectively, and M rotator rows corresponding to the insert rows, respectively.

For example, the rod may be provided with the match frame along the insert column and even-numbered rotator columns may be shifted downwards from a top portion of the match frame by a first shifting distance, so that odd-numbered rotator columns may be higher than the even-numbered rotator columns along the rod and the first and the second pusher assemblies combined to the neighboring rotators may be rotated without colliding to each other in an inter-space between the neighboring rotators in the rotator row.

For example, the rod may be provided with the match frame along the insert row and even-numbered rotator rows may be shifted rightwards from a left portion of the match frame by a second shifting distance, so that odd-numbered rotator rows may be closer to the left portion of the match frame than the even-numbered rotator rows along the rod and the first and the second pusher assemblies combined to the neighboring rotators may be rotated without colliding to each other in an inter-space between the neighboring rotators in the rotator column.

For example, the first pusher assembly may include a first pusher that may be arranged on the base body and make contact with the DUT to push the DUT towards a test socket and a cooler that may be combined to the first pusher and cool the DUT down to a first temperature by thermal conduction, and the second pusher assembly may include a second pusher that may be arranged in a second portion of the base body and make contact with the DUT to push the DUT towards the test socket and a heater that may be combined to the second pusher and heat the DUT up to a second temperature by thermal conduction.

For example, the first pusher assembly may include a pusher that may be arranged on the base body and make contact with the DUT to push the DUT towards a test socket and a cooling tip that may be detachably combined to the pusher and cool the DUT down by thermal conduction, and the second pusher assembly may include the pusher and a heating tip that may be detachably combined to the pusher and heat the DUT up by thermal conduction.

For example, multiple DUTs may be received in multiple inserts that may be arranged in an M×N insert matrix in a test tray, and multiple pushers may be arranged on the base body in an M×N pusher matrix, and further comprising a first receiving plate having multiple first holes that may be arranged in correspondence to the M×N pusher matrix and receives the cooling tips, a cooling chamber to which the first receiving plate may be moved and cooling down multiple cooling tips for a cold test to the DUTs, a second receiving plate having multiple second holes that may be arranged in correspondence to the M×N pusher matrix and receive the heating tips, and a heating chamber to which the second receiving plate may be moved and heating up multiple heating tips for a hot test to the DUTs.

According to other embodiments, there is provided a test handler including a test head having a test socket through which testing signals may be applied to the device under test (DUT) and responsive signals may be detected from the DUT in response to the testing signals, a test chamber connected to the test head such that a test tray receiving multiple DUTs may be arranged in correspondence to the test socket, and a contact structure positioned in the test chamber and bringing the DUTs in the test tray into contact with sockets of the test socket, respectively. In such a case, the contact structure may include a base body driven by a driving unit, multiple first pusher assemblies arranged on the base body and making contact with the DUTs, respectively, thereby pushing and cooling each of DUTs, and multiple second pusher assemblies arranged on the base body individually from the first pusher assemblies and making contact with the DUTs, respectively, thereby pushing and heating each of the DUTs.

For example, the base body may include a plate, and multiple first pusher assemblies may be arranged on a first portion of the plate matching with the test tray and multiple second pusher assemblies may be arrange on a second portion of the plate matching with the test tray.

For example, multiple DUTs may be received in multiple inserts of the test tray in such a configuration that the inserts may be arranged in an M×N insert matrix having N (N is an integer number over 1) insert columns M (M is an integer number over 1) insert rows, and multiple first and the second pusher assemblies may be arranged on the base body in an M×(N+1) pusher matrix in which an M×1 first pusher column, which denotes multiple first pusher assemblies that may be arranged in series on the base body in correspondence to multiple inserts in the insert column, and an M×1 second pusher column, which denotes multiple second pusher assemblies that may be arranged in series in correspondence to multiple inserts in the insert column, may be alternately arranged on the base body.

For example, the base body may include a match frame matching with the test tray, multiple rods installed to the match frame and multiple rotators combined to each rod and having first and second surfaces opposite to each other in such a configuration that the first pusher assembly may be combined to the first surface and the second pusher assembly may be combined to the second surface, thus the first and the second pusher assemblies may be alternately brought into contact with the DUT by rotation of the rotator.

For example, the first pusher assembly may include a pusher that may be arranged on the base body and makes contact with the DUT to push the DUT towards the test socket and a cooling tip that may be detachably combined to the pusher and cool the DUT down by thermal conduction; and the second pusher assembly may include the pusher and a heating tip that may be detachably combined to the pusher and heat the DUT up by thermal conduction.

For example, multiple DUTs may be received in multiple inserts that may be arranged in an M×N insert matrix in the test tray, and multiple pushers may be arranged on the base body in an M×N pusher matrix, and further comprising a first receiving plate having multiple first holes that may be arranged in correspondence to the M×N pusher matrix and receive the cooling tips, a cooling chamber to which the first receiving plate may be moved and cool down multiple cooling tips for a cold test to the DUTs, a second receiving plate having multiple second holes that may be arranged in correspondence to the M×N pusher matrix and receive the heating tips, and a heating chamber to which the second receiving plate may be moved and heat up multiple heating tips for a hot test to the DUTs.

Other embodiments include a method of electrically testing a semiconductor device. A test tray having multiple inserts may be prepared in such a way that at least a semiconductor device under test (DUT) is received in each insert. The test tray may be loaded into a test chamber such that the test tray may face a test socket of a test head and the DUTs may be arranged with sockets of the test socket, respectively. A cold test and a hot test may be alternately conducted to the DUT by exchanging first and second pusher assemblies that may be individually positioned in the test chamber, thereby electrically testing the DUT. The first pusher assembly may push the DUT to the socket and cool down the DUT for the cold test by a thermal conduction. The second pusher assembly may push the DUT to the socket and heat up the DUT for the hot test by a thermal conduction. Then, the test tray receiving tested semiconductor devices may be unloaded from the test chamber.

For example, the cold test and the hot test may be performed to the DUT as follows in accordance with an embodiment. Multiple first pusher assemblies may be arranged to multiple DUTs. Then, the first pusher assemblies may be simultaneously brought into contact with the DUTs, respectively, together with cooling down the DUTs such that the DUTs may be pushed into the sockets, respectively, under a first temperature, and the cold test may be performed to the DUTs under the first temperature. Multiple second pusher assemblies may be arranged to the DUTs after separating the first pusher assemblies from the DUTs. The second pusher assemblies may be simultaneously brought into contact with the DUTs, respectively, together with heating up the DUT such that the DUTs may be pushed into the sockets, respectively, under a second temperature higher than the first temperature, and the hot test may be performed to the DUTs under the second temperature.

For example, the cold test and the hot test may be performed to the DUT as follows in accordance with another embodiment. The test tray having the inserts in an M×N insert matrix may be arranged with a contact structure having the first and the second pusher assemblies in an M×(N+1) pusher matrix in which an M×1 first pusher column and an M×1 second pusher column may be alternately arranged in correspondence to an M×1 insert column. Then, the first and the second pusher assemblies in an M×N first sub-pusher matrix having a 1^{st} pusher column to N^{th} pusher column may be simultaneously brought into contact with the DUTs in the M×N insert matrix in such a manner that the DUTs in the M×1 insert column making contact with the M×1 first pusher column may be cooled down to a first temperature for the cold test and the DUTs in the M×1 insert column making contact with the M×1 second pusher column may be heated up to a second temperature for the hot test. A first electrical test may be performed to the DUTs in the M×N insert matrix in such a manner that the cold test and the hot test may be simultaneously conducted to every alternate M×1 insert column. Then, the test tray may be moved in a row direction by the M×1 insert column. The first and the second pusher assemblies in an M×N second sub-pusher matrix having a 2^{nd} pusher column to (N+1)^{th} pusher column may be simultaneously brought into contact with the DUTs in the M×N insert matrix in such a manner that the DUTs in the M×1 insert column making contact with the M×1 first pusher column may be cooled down to the first temperature for the cold test and the DUTs in the M×1 insert column making contact with the M×1 second pusher column may be heated up to the second temperature for the hot test. A second electrical test may be performed to the DUTs in the M×N insert matrix in such a manner that the cold test and the hot test may be simultaneously conducted to every alternate M×1 insert column.

For example, the cold test and the hot test may be performed to the DUT as follows in accordance with still another embodiment. The test tray having the inserts in an M×N insert matrix may be arranged with a contact structure having multiple rotator that may be rotatably provided in an M×N rotator matrix with a match frame matching with the test tray while a pair of the first and the second pusher assemblies may be provided with each of the rotators. The first pusher assemblies may be simultaneously brought into contact with the DUTs, respectively, together with cooling down the DUTs such that the DUTs may be pushed into the sockets, respectively, under a first temperature, and the cold test may be performed to the DUTs under the first temperature. Then, the rotator may be rotated in such a way that the first pusher assemblies may be separated from the DUTs and the second pusher assemblies may face the DUTs in the test tray. The second pusher assemblies may be simultaneously brought into contact with the DUTs, respectively, together with heating up the DUTs such that the DUTs may be pushed into the sockets, respectively, under a second temperature, and then the hot test may be performed to the DUTs under the second temperature.

According to some embodiments, the first pusher assembly for the cold test and the second pusher assembly for the hot test may be individually arranged in the same test chamber. In such a configuration, the first pusher assembly may be controlled to have the first temperature for the cold test and the second pusher assembly may be controlled to have the second temperature for the hot test. Thus, the first and the second pusher assemblies may be brought into contact with the DUTs under the first temperature for the cold test and the second temperature for the hot test, respectively.

As a result, the cold test and the hot test to the same DUT may be easily converted just by interchanging the first and the second pusher assemblies without substantial temperature conversion time in the same test chamber, thereby sufficiently reducing an overall electrical test time to the DUT.

The foregoing is illustrative of particular embodiments and is not to be construed as limiting thereof. Although some embodiments have been described, those skilled in the art will readily appreciate that many modifications are possible in these and other embodiments without materially departing from the novel teachings and advantages. Accordingly, all such modifications are intended to be included within the scope as defined in the claims. In the claims, means-plus-function clauses are intended to cover the structures described herein as performing the recited function and not only structural equivalents but also equivalent structures. Therefore, it is to be understood that the foregoing is illustrative of various particular embodiments as examples and is not to be construed as limited to the specific embodiments disclosed, and that modifications to the disclosed embodiments, as well as other embodiments, are intended to be included within the scope of the appended claims.

What is claimed is:

1. A contact structure for a test handler for electrically testing a semiconductor device, comprising:
a base body configured to be driven by a driving unit;
at least one first pusher assembly arranged on the base body and configured to push and cool the semiconductor device; and
at least one second pusher assembly arranged on the base body and configured to push and heat the semiconductor device.

2. The contact structure of claim 1, wherein the at least one first pusher assembly and the at least one second pusher are each configured to make contact with the semiconductor device.

3. The contact structure of claim 1, wherein the base body includes a plate, and a plurality of the first pusher assemblies are arranged on a first portion of the plate corresponding to a test tray configured to receive the semiconductor device and a plurality of the second pusher assemblies is arrange on a second portion of the plate matching with the test tray.

4. The contact structure of claim 3, wherein the first and the second portions of the base body are separated into first and second match plates that are independent from each other and have a shape corresponding to the test tray.

5. The contact structure of claim 1, further comprising:
a test tray configured to receive the semiconductor device, the test tray including a plurality of inserts configured to receive semiconductor devices arranged in an M×N insert matrix where M and N are integers;
wherein the at least one first pusher assembly and the at least one second pusher assembly comprise a plurality of first and second pusher assemblies arranged on the base body in an M×(N+1) pusher matrix.

6. The contact structure of claim 1, further comprising a match frame including a plurality of rods configured to rotate, wherein the at least one first pusher and the at least one second pusher assembly are disposed on the rods such that first pusher assemblies are disposed on opposite sides of the rods than respective second pusher assemblies.

7. The contact structure of claim 6, wherein the at least one first pusher assembly and the at least one second pusher assembly are arranged in an M×N rotator matrix having N rotator columns and M rotator rows.

8. The contact structure of claim 7, wherein the at least one first pusher assembly and the at least one second pusher assembly are disposed on the rods such that pusher assemblies of the at least one first pusher assembly and the at least one second pusher assembly are offset along the respective rod relative to pusher assemblies on adjacent rods.

9. The contact structure of claim 7, wherein the rods are offset from each other such that the pusher assemblies of a rod does not contact pusher assemblies of adjacent rods.

10. The contact structure of claim 1, wherein:
the at least one first pusher assembly comprises a cooler configured to contact the semiconductor device; and
the at least one second pusher assembly comprises a heater configured to contact the semiconductor device.

11. The contact structure of claim 1, further comprising:
a plurality of cooling tips configured to be attachable and detachable to the at least one first pusher assembly; and
a plurality of heating tips configured to be attachable and detachable to the at least one second pusher assembly.

12. The contact structure of claim 11, further comprising:
a cooling chamber configured to cool the cooling tips; and
a heating chamber configured to heat the heating tips.

13. A test handler for electrically testing a semiconductor device, comprising:
a test head having test sockets configured to apply testing signals to a devices under test (DUTs) and responsive signals are detected from the DUTs;
a test chamber connected to the test head and configured to receive a test tray including a plurality of DUTs arranged in correspondence to the test socket; and
a contact structure positioned in the test chamber and configured to bring the DUTs in the test tray into contact with sockets of the test socket, respectively,
wherein the contact structure includes:
a base body configured to be moved by a driving unit;
a plurality of first pusher assemblies arranged on the base body and configured to push and cool each of DUTs; and
a plurality of second pusher assemblies arranged on the base body separate from the first pusher assemblies and configured to pushing and heat each of the DUTs.

14. The test handler of claim 13, wherein the base body includes a plate, and the plurality of the first pusher assemblies are arranged on a first portion of the plate corresponding to the test tray and a plurality of the second pusher assemblies arranged on a second portion of the plate corresponding with the test tray.

15. A contact structure for a test handler for electrically testing a semiconductor device, comprising:
a test socket configured to receive a plurality of devices under test (DUTs);
a plurality of first pusher assemblies, each first pusher assembly configured to push a first at least one of the DUTs towards the test socket;
a plurality of second pusher assemblies, each second pusher assembly configured to push a second at least one of the DUTs towards the test socket;
a driving unit coupled to the first and second pusher assemblies and configured to move the first and second pusher assemblies such that each DUT is contacted by a first pusher assembly during a first test and by a second pusher assembly during a second test.

16. The contact structure of claim 15, wherein the first test is performed at a first temperature and the second test is performed at a second temperature.

17. The contact structure of claim 15, wherein the first and second pusher assemblies are coupled to the driving unit such that during a test of the DUTs, at least one DUT is pushed by a first pusher assembly and at least one other DUT is pushed by a second pusher assembly.

18. The contact structure of claim 15, further comprising:
a plurality of cooling tips;
a plurality of heating tips;
a first plate configured to move the cooling tips to the first and second pusher assemblies; and
a second plate configured to move the heating tips to the first and second pusher assemblies.

19. The contact structure of claim 15, wherein:
the first pusher assemblies are disposed on a first plate and configured to cool the DUTs when pushing the DUTs; and
the second pusher assemblies are disposed on a second plate and configured to heat the DUTs when pushing the DUTs.

20. The contact structure of claim 15, wherein the first and second pusher assemblies are disposed on a single plate and arranged such at each first pusher assembly is adjacent to a corresponding second pusher assembly in a single direction.
